(19) United States
(12) Patent Application Publication
(10) Pub. No.: US 2026/0007007 A1
(43) Pub. Date: Jan. 1, 2026

(54) DISPLAY DEVICE

(71) Applicant: Samsung Display Co., Ltd., Yongin-Si (KR)

(72) Inventors: Gi Na YOO, Yongin-si (KR); Hyo Min KIM, Yongin-si (KR); Hyun Gue SONG, Yongin-si (KR)

(21) Appl. No.: 19/060,351

(22) Filed: Feb. 21, 2025

(30) Foreign Application Priority Data
Jun. 26, 2024 (KR) 10-2024-0083777

(51) Int. Cl. H10K 59/126; H10K 59/38

(52) U.S. Cl. CPC H10K 59/126; H10K 59/38

(57) ABSTRACT

A display device includes pixels, each including a first emission area, a second emission area, and a third emission area, color filters disposed in the emission areas of the pixels and a non-emission area at the periphery of the emission areas, a first light blocking layer formed by overlapping at least two of the color filters in the non-emission area, and a second light blocking layer disposed on the first light blocking layer and surrounding the emission areas of a subgroup of the pixels, wherein the color filter disposed at the lower portion of the first light blocking layer includes ring-shaped openings surrounding the emission areas of the subgroup of pixels.

### CROSS-REFERENCE TO RELATED APPLICATION

This application claims priority and the benefits accruing under 35 U.S.C. 119 from Korean Patent Application No. 10-2024-0083777, filed on Jun. 26, 2024 in the Korean Intellectual Property Office, the contents of which in its entirety are incorporated herein by reference.

### BACKGROUND

### 1. Technical Field

The present disclosure relates to a display device.

### 2. Description of the Related Art

In today's information-oriented society, increasing demands are placed on display devices for displaying images in various ways. To meet this increasing demand, various types of display devices including a light emitting display device are being developed.

### SUMMARY

Aspects of the present disclosure provide a display device capable of varying a side viewing angle of an image displayed in a display area and preventing light leakage of side light emitted from at least some pixels.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including, pixels, each pixel of the pixels including emission areas including a first emission area, a second emission area, and a third emission area, and light emitting elements disposed in the emission areas, a first color filter disposed on the light emitting elements and disposed in the first emission areas of the pixels and a non-emission area at the periphery of the emission areas, a second color filter disposed on the light emitting elements and disposed in the second emission areas of the pixels and the non-emission area, a third color filter disposed on the light emitting elements and disposed in the third emission areas of the pixels and the non-emission area, a first light blocking layer formed by overlapping the first color filter, the second color filter, and the third color filter in the non-emission area, and a second light blocking layer disposed on the first light blocking layer and surrounding the emission areas of a subgroup of the pixels, wherein the color filter disposed at the lowermost portion of the first light blocking layer among the first color filter, the second color filter, and the third color filter includes ring-shaped openings surrounding the emission areas of the subgroup of the pixels.

In an embodiment, the ring-shaped openings may be filled with other color filter disposed on the color filter that is at the bottom of the first light blocking layer.

In an embodiment, the pixels may include first pixels and second pixels, and wherein the second light blocking layer is disposed in the second pixels and absent from the first pixels, and the second light blocking layer may be disposed in the non-emission area of the second pixels and may surround the emission areas of the second pixels.

In an embodiment, the ring-shaped openings may be absent from the non-emission area of the first pixels and disposed in the non-emission area of the second pixels.

In an embodiment, the ring-shaped openings may be disposed in the non-emission area of the first pixels and in the non-emission area of the second pixels.

In an embodiment, the number of the ring-shaped openings disposed in the non-emission area of the first pixels and the number of the ring-shaped openings disposed in the non-emission area of the second pixels may be different.

In an embodiment, the number of the ring-shaped openings disposed in the non-emission area of the second pixels may be greater than the number of the ring-shaped openings disposed in the non-emission area of the first pixels.

In an embodiment, the size of the ring-shaped openings disposed in the non-emission area of the first pixels and the size of the ring-shaped openings disposed in non-emission area of the second pixels may be different.

In an embodiment, the size of the ring-shaped openings disposed in the non-emission area of the second pixels may be larger than the size of the ring-shaped openings disposed in the non-emission area of the first pixels.

In an embodiment, the first light blocking layer may include openings in the emission areas of the first pixels and openings in the emission areas of the second pixels, and the size of the openings of the first light blocking layer in the emission areas of the first pixels and the size of the openings of the first light blocking layer in the emission areas of the second pixels may be different.

In an embodiment, the size of the openings of the first light blocking layer in the emission areas of the first pixels may be larger than the size of the openings of the first light blocking layer in the emission areas of the second pixels.

In an embodiment, the light emitting elements may include respective pixel electrodes disposed in the emission areas of the first pixels and the second pixels, respective light emitting layers disposed on the pixel electrodes, and a common electrode disposed on the light emitting layers.

In an embodiment, a separation distance between the openings of the first light blocking layer in the emission areas of the first pixels and the pixel electrodes disposed in the first pixels may be greater than a separation distance between the openings of the first light blocking layer in the emission areas of the second pixels and the pixel electrodes disposed in the second pixels.

In an embodiment, the sizes of the first emission area, the second emission area, and the third emission area of each pixel may be different.

In an embodiment, in the subgroup of pixels, at least one of the size and the number of two or more ring-shaped openings among the ring-shaped opening of the first light blocking layer surrounding the first emission area, the ring-shaped opening of the first light blocking layer surrounding the second emission area, and the ring-shaped opening of the first light blocking layer surrounding the third emission area may be different.

In an embodiment, the color filter disposed on the middle layer of the first light blocking layer among the first color filter, the second color filter, and the third color filter may include ring-shaped openings surrounding the emission areas of the subgroup of pixels.

In an embodiment, the ring-shaped openings of the color filter disposed at the middle layer of the first light blocking layer may not overlap the ring-shaped openings of the color filter disposed at the lowermost portion of the first light blocking layer.

In an embodiment, the color filter disposed at the uppermost portion of the first blocking layer among the first color filter, the second color filter, and the third color filter may not include ring-shaped openings in the non-emission area.

In an embodiment, each of the pixels may include a first light emitting element disposed in the first emission area and emitting red light, a second light emitting element disposed in the second emission area and emitting green light, and a third light emitting element disposed in the third emission area and emitting blue light, and the first color filter, the second color filter, and the third color filter may selectively transmit the red light, the green light, and the blue light, respectively.

In an embodiment, the first or third color filter may be disposed on the lowermost portion of the first light blocking layer in the non-emission area, and the second color filter may be disposed on the uppermost portion of the first light blocking layer in the non-emission area.

In accordance with a display device according to embodiments, the light exit angle or side viewing angle of pixels disposed in the display area may be differentiated or optimized by a first light blocking layer and a second light blocking layer. Accordingly, the side viewing angle of the image displayed in the display area may be appropriately or easily varied in response to each emission mode selected by a user.

Further, in accordance with a display device according to embodiments, a first light blocking layer may be formed by stacking color filters disposed in each of the emission areas in a non-emission area. Accordingly, the manufacturing efficiency of the display device may be increased.

Additionally, in accordance with a display device according to embodiments, rings may be formed in the color filter disposed at the bottom of the first light blocking layer in at least some of the pixels, including pixels in which the light exit angle or side viewing angle is limited to a narrower range. Accordingly, a light blocking function of the first blocking layer formed by stacking of the color filters may be improved, and light leakage of side light may be effectively prevented.

In another aspect, the disclosure pertains to an electronic device including a display device that has first pixels, second pixels, and a display driver transmitting data to the first pixels and second pixels to display images. Each of the second pixels includes a first emission area, a second emission area, and a third emission area separated by a non-emission area, a first light blocking layer that has a lower color filter and an upper color filter overlapping in the non-emission area, and a second light blocking layer disposed on the first light blocking layer and surrounding the first emission area, the second emission area, and the third emission area. The lower color filter of the first light blocking layer has ring-shaped openings surrounding the first emission area, the second emission area, and the third emission area. However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view showing an electronic device according to one embodiment;

FIG. 2 is a perspective view illustrating a display device included in an electronic device according to one embodiment;

FIG. 3 is a cross-sectional view of the display device of FIG. 2 viewed from the side;

FIG. 4 is a plan view illustrating a display area of a display device according to one embodiment;

FIG. 5 is a plan view illustrating pixel electrodes according to one embodiment;

FIG. 6 is a plan view showing pixel electrodes, a first light blocking layer, and color filters according to one embodiment;

FIG. 7 is a plan view showing pixel electrodes and a second light blocking layer according to one embodiment;

FIG. 8 is a plan view illustrating a display area of a display device according to one embodiment;

FIG. 9 is a cross-sectional view illustrating a display device according to one embodiment;

FIG. 10 is a cross-sectional view showing a display device according to one embodiment;

FIG. 11 is a cross-sectional view showing a display device according to one embodiment;

FIG. 12 is a cross-sectional view illustrating a display device according to one embodiment;

FIG. 13 is a cross-sectional view showing a display device according to one embodiment;

FIG. 14 is a cross-sectional view illustrating a display device according to one embodiment;

FIG. 15 is a plan view illustrating a first color filter according to one embodiment;

FIG. 16 is a plan view illustrating a second color filter according to one embodiment;

FIG. 17 is a plan view illustrating a third color filter according to one embodiment; and

FIGS. 18 to 21 are plan views showing a third color filter according to embodiments.

### DETAILED DESCRIPTION OF THE EMBODIMENTS

The present inventive concept will now be described more fully hereinafter with reference to the accompanying drawings, in which preferred embodiments are shown. This inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited to any order or priority by these terms. These terms are only used to distinguish one element from another element. For instance, a first element discussed below could be termed a second element without departing from the teachings of the present disclosure. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

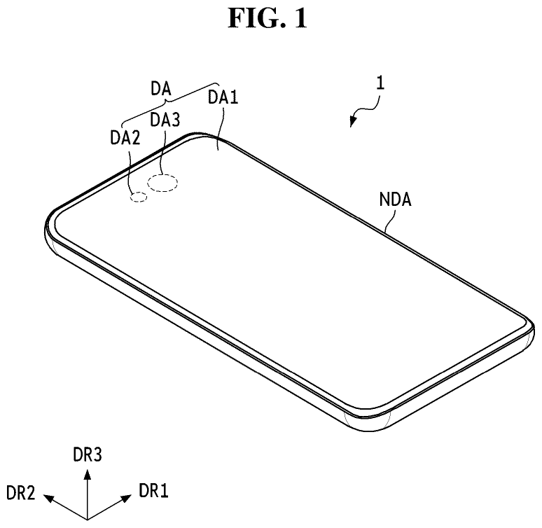

FIG. 1 is a perspective view showing an electronic device according to one embodiment.

Referring to FIG. 1, an electronic device 1 displays a moving image or a still image. The electronic device 1 may refer to any electronic device providing a display screen. Examples of the electronic device 1 may include a television, a laptop computer, a monitor, a billboard, an Internet-of-Things device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder and the like, which provide a display screen.

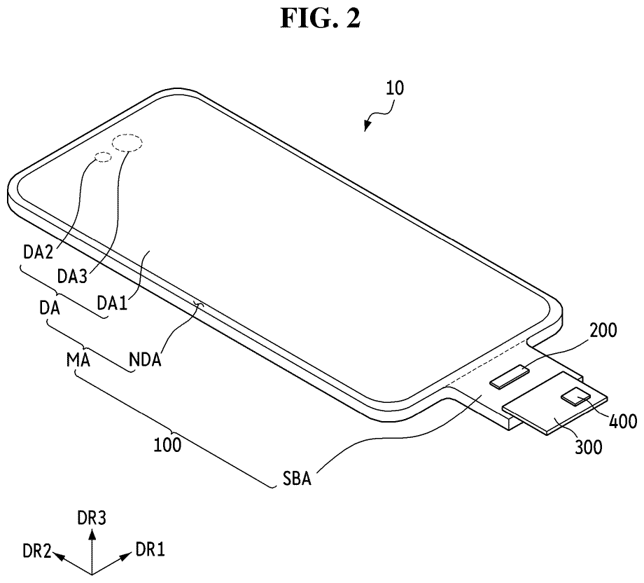

The electronic device 1 may include a display device (e.g., a display device 10 of FIG. 2) that provides a display screen. In one embodiment, the display device may be a light emitting display device including a light emitting element such as an inorganic light emitting diode or an organic light emitting diode, but is not limited thereto. For example, although a light emitting display device including an organic light emitting diode is described as a display device to which embodiments may be applied, devices or fields to which embodiments may be applied are not limited thereto. For example, embodiments may also be applied to other types of display devices.

The shape of the electronic device 1 may be modified. For example, the electronic device 1 may have a shape such as a rectangular shape elongated in a horizontal direction, a rectangular shape elongated in a vertical direction, a square shape, a substantially quadrilateral shape with rounded corners, other polygonal shapes and a circular shape. In one embodiment, the shape of a display area DA of the electronic device 1 may be similar to the overall shape of the electronic device 1, but is not limited thereto. In FIG. 1, the electronic device 1 having a rectangular shape that is longer in a second direction DR2 than in a first direction DR1 is exemplified.

The electronic device 1 may include the display area DA and a non-display area NDA. The display area DA is an area where an image can be displayed, and the non-display area NDA is an area where an image is not displayed. The display area DA may also be referred to as an active region, and the non-display area NDA may also be referred to as a non-active region. The display area DA may substantially occupy the center of the electronic device 1.

The display area DA may include a first display area DA1, a second display area DA2, and a third display area DA3. The second display area DA2 and the third display area DA3 are areas in which components for adding various functions to the electronic device 1 are disposed, and the second display area DA2 and the third display area DA3 may correspond to a component area. Although FIG. 1 shows an embodiment in which the electronic device 1 includes two component areas, the number or location of the component areas is not limited.

FIG. 2 is a perspective view illustrating a display device included in an electronic device according to one embodiment.

Referring to FIG. 2, the electronic device 1 according to one embodiment may include the display device 10. The display device 10 may provide a screen of the electronic device 1. The display device 10 may have a planar shape similar to the shape of the electronic device 1. For example, the display device 10 may have a shape similar to a rectangular shape having a short side in the first direction DR1 and a long side in the second direction DR2. The edge where the short side in the first direction DR1 and the long side in the second direction DR2 meet may be rounded, but is not limited thereto and may be formed at a right angle. The planar shape of the display device 10 is not limited to a quadrilateral shape, and may have another polygonal shape, a circular shape, an elliptical shape, or another shape.

The display device 10 may include a display panel 100, a display driver 200, a circuit board 300, and a touch driver 400.

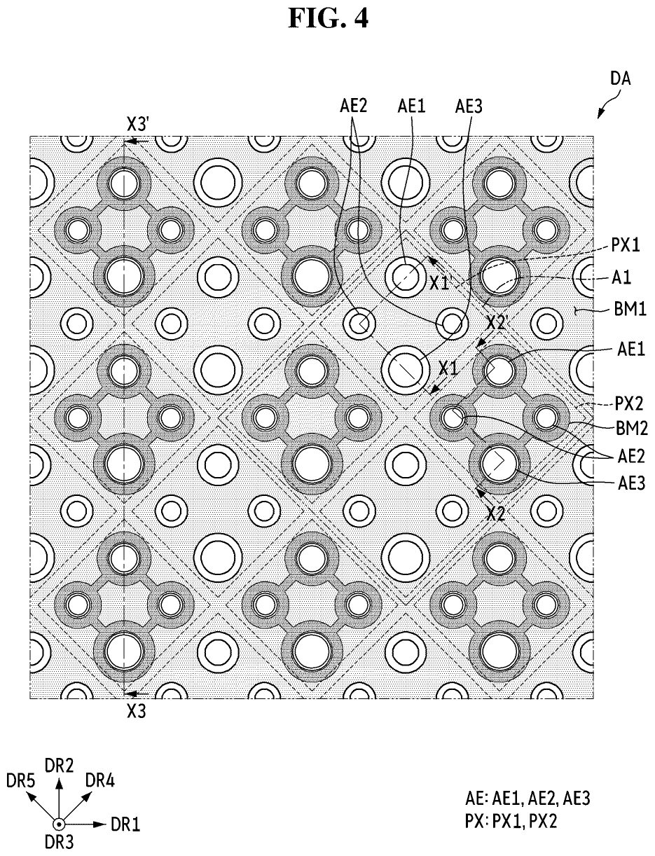

The display panel 100 may include a main region MA and a sub-region SBA. The main region MA may include the display area DA including pixels PX (e.g., pixels PX of FIG. 4) displaying an image and the non-display area NDA disposed around the display area DA. The display area DA may be disposed in the center of the main region MA, and the non-display area NDA may surround the display area DA.

The display area DA may include the first display area DA1, the second display area DA2, and the third display area DA3. The display area DA may include emission areas (or opening areas) of the pixels PX, and light may be emitted from the emission areas.

The display panel 100 may include light emitting elements and pixel circuits (e.g., pixel circuits including transistors and capacitors) of the pixels PX, and a pixel defining film defining the emission areas of the pixels PX. The light emitting element of each of the pixels PX may be disposed in the emission area of the corresponding pixel PX. In one embodiment, the light emitting element may include one of an organic light emitting diode (LED) including an organic light emitting layer, a quantum dot LED including a quantum dot light emitting layer, an inorganic LED including an inorganic semiconductor, and an ultra-small light emitting diode such as a micro LED or nano LED, but is not limited thereto.

The non-display area NDA may be an area outside the display area DA. The non-display area NDA may be defined as an edge area of the main region MA of the display panel 100. In one embodiment, the non-display area NDA may include a gate driver (not illustrated) that supplies gate signals to the gate lines, and fan-out lines (not illustrated) that connect the display driver 200 to the display area DA.

The sub-region SBA may be a region extending from one side of the main region MA. The sub-region SBA may include a flexible material which can be bent, folded or rolled. For example, when the sub-region SBA is bent (or folded), the sub-region SBA may overlap the main region MA in a thickness direction (third direction DR3). For example, when the display device 10 is bent in the sub-region SBA, at least a part of the sub-region SBA including an area where the display driver 200 is disposed and an area where a pad portion connected to the circuit board 300 is disposed may be disposed under the main region MA.

The sub-region SBA may include the display driver 200 and a pad portion connected to the circuit board 300. In another embodiment, the sub-region SBA may be omitted, and the display driver 200 and the pad portion may be disposed in the non-display area NDA. In another embodiment, the display driver 200 may be disposed on the circuit board 300 connected to the display panel 100 and may be electrically connected to the display panel 100 through the pad portion.

The display driver 200 may output driving signals and driving voltages for driving the display panel 100. For example, the display driver 200 may supply data voltages to data lines, supply driving voltages (e.g., first pixel voltage (or anode voltage) and second pixel voltage (or cathode voltage)) to power lines, and supply gate control signals to the gate driver. In one embodiment, the display driver 200 may be formed as an integrated circuit (IC) and mounted on the display panel 100 by a chip on glass (COG) method, a chip on plastic (COP) method, or an ultrasonic bonding method.

The circuit board 300 may be attached to the pad portion of the display panel 100 by using an anisotropic conductive film (ACF) or the like. Lead lines of the circuit board 300 may be electrically connected to the pad portion of the display panel 100. In one embodiment, the circuit board 300 may be a flexible printed circuit board, a printed circuit board, or a flexible film such as a chip on film.

The touch driver 400 may be mounted on the circuit board 300. The touch driver 400 may be connected to a touch sensing unit of the display panel 100. The touch driver 400 may supply each touch drive signal to touch electrodes of the touch sensing unit, and may sense the amount of change in capacitance formed between the touch electrodes. In one embodiment, the touch driving signal may be a pulse signal having a predetermined frequency. The touch driver 400 may detect whether or not a touch input has occurred, and coordinates based on the amount of change in capacitance between the touch electrodes. In one embodiment, the touch driver 400 may be formed as an integrated circuit (IC).

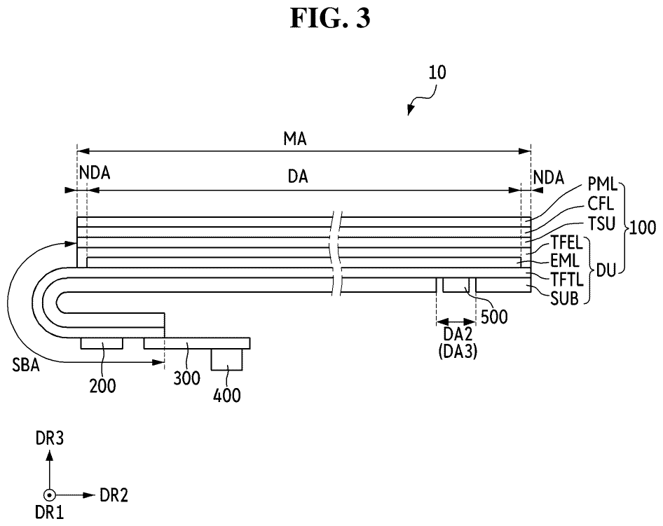

FIG. 3 is a cross-sectional view of the display device of FIG. 2 viewed from the side. FIG. 3 illustrates the sub-region SBA of the display panel 100 in a bent state in the display device 10 of FIG. 2.

Referring to FIG. 3, the display panel 100 may include a display layer DU, a touch sensing layer TSU, a color filter layer CFL, and a light blocking member layer PML. Although the color filter layer CFL and the light blocking member layer PML are separately illustrated in FIG. 3, the color filter layer CFL and the light blocking member layer PML may be integrated into one light control layer.

The display layer DU may include a substrate SUB, a thin film transistor layer TFTL, a light emitting element layer EML, and an encapsulation layer TFEL.

The substrate SUB may be a base substrate or a base member. The substrate SUB may be a flexible substrate which can be bent, folded or rolled, but is not limited thereto. In one embodiment, the substrate SUB may include a polymer resin such as polyimide (PI). In another embodiment, the substrate SUB may include a glass material or a metal material.

The thin film transistor layer TFTL may be disposed on the substrate SUB. The thin film transistor layer TFTL may include circuit elements, e.g., thin film transistors and capacitors, constituting pixel circuits of pixels. The thin film transistor layer TFTL may further include wires. For example, the thin film transistor layer TFTL may further include gate lines, data lines, power lines, gate control lines, fan-out lines that connect the display driver 200 to the data lines, and lead lines that connect the display driver 200 to the pad portion. Each of the thin film transistors may include a semiconductor region, a source electrode, a drain electrode, and a gate electrode. In one embodiment, when the display panel 100 includes the gate driver disposed in the non-display area NDA, the thin film transistor layer TFTL may further include circuit elements constituting the gate driver.

The thin film transistor layer TFTL may be disposed in the display area DA, the non-display area NDA, and the sub-region SBA. The circuit elements constituting the pixel circuits of the pixels, and the gate lines, the data lines, and the power lines that are electrically connected to the pixels may be disposed in the display area DA of the thin film transistor layer TFTL. The gate lines, the data lines, and the power lines may extend to the non-display area NDA of the thin film transistor layer TFTL, and may be respectively electrically connected to the gate driver, the display driver 200, or the pad portion. The gate control lines and the fan-out lines may be disposed in the non-display area NDA of the thin film transistor layer TFTL. The lead lines may be disposed in the sub-region SBA of the thin film transistor layer TFTL.

The light emitting element layer EML may be disposed on the thin film transistor layer TFTL. The light emitting element layer EML may include a pixel defining film that defines emission areas of pixels, and light emitting elements disposed in the emission areas. Each emission area may be disposed in each pixel area of the display area DA. For example, the pixel area where the respective pixels of the display area DA are disposed may include a pixel circuit area where circuit elements constituting the pixel circuit of the corresponding pixel are disposed and an emission area where the light emitting element of the corresponding pixel is disposed. In one embodiment, the emission area and the pixel circuit area of each pixel may overlap each other in the third direction DR3.

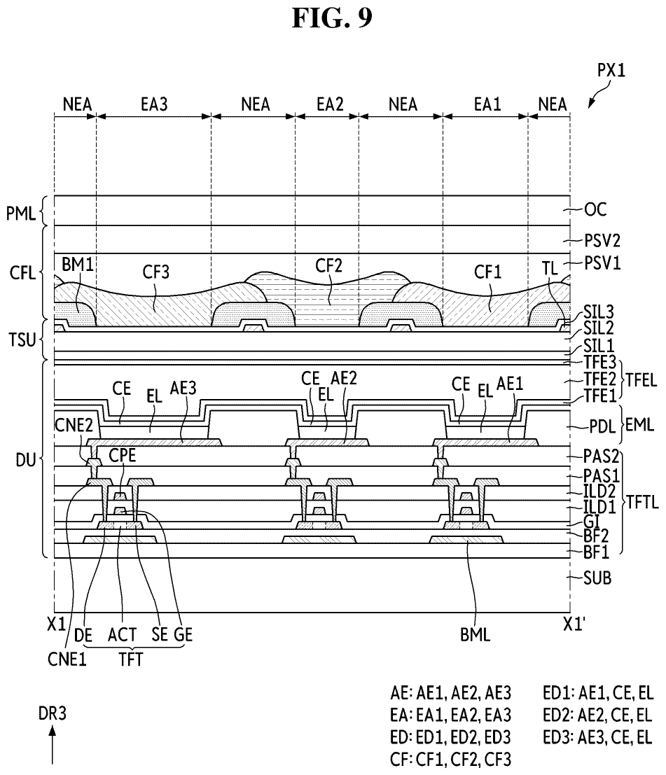

The light emitting element may include a first electrode and a second electrode facing each other, and a light emitting layer interposed between the first electrode and the second electrode. In one embodiment, the first electrode of the light emitting element may correspond to the pixel electrode shown in FIG. 4 and subsequent drawings, and the second electrode of the light emitting element may correspond to the common electrode shown in FIG. 9 and subsequent drawings. In one embodiment, the light emitting layer may be an organic light emitting layer including an organic material. The light emitting layer may include a hole transporting layer, an organic light emitting layer, and an electron transporting layer. When a first pixel voltage (e.g., anode voltage) is applied to the first electrode of the light emitting element through at least one of the thin film transistors of each pixel circuit, and a second pixel voltage (e.g., cathode voltage) is applied to the second electrode of the light emitting element through the power line, holes and electrons may recombine in an organic light emitting layer and the light emitting element may emit light. In another embodiment, the light emitting element may be another type of light emitting element, such as a quantum dot light emitting diode including a quantum dot light emitting layer, an inorganic light emitting diode including an inorganic semiconductor, a micro light emitting diode, or a nano light emitting diode.

The encapsulation layer TFEL may cover the top surface and the side surface of the light emitting element layer EML, and may protect the light emitting element layer EML. In one embodiment, the encapsulation layer TFEL may include at least one inorganic film and at least one organic film for encapsulating the light emitting element layer EML. For example, the encapsulation layer TFEL may include a plurality of inorganic encapsulation layers and an organic encapsulation layer interposed between the inorganic encapsulation layers.

The touch sensing layer TSU may be disposed on the display layer DU. For example, the touch sensing layer TSU may be disposed or formed on the encapsulation layer TFEL, or the touch sensing layer TSU may be disposed on a separate substrate disposed on the display layer DU.

The touch sensing layer TSU may include touch electrodes for sensing the user's touch input, and touch lines that electrically connect the touch electrodes to the touch driver 400. In one embodiment, the touch sensing layer TSU may sense the user's touch in a mutual capacitance manner or a self-capacitance manner, and the touch electrodes may have a shape for constituting a mutual capacitance type or self-capacitance type touch sensor. For example, the touch electrodes may include driving electrodes and sensing electrodes extending and/or connected in different directions to constitute a mutual capacitance type touch sensor, or may include touch electrodes disposed at points corresponding to respective touch nodes to constitute a self-capacitance type touch sensor.

The touch electrodes of the touch sensing layer TSU may be disposed in a touch sensor area overlapping the display area DA. Touch lines electrically connected to the touch electrodes of the touch sensing layer TSU may be disposed in a peripheral area overlapping the non-display area NDA.

The color filter layer CFL may be disposed on the touch sensing layer TSU. The color filter layer CFL may include color filters corresponding to the respective emission areas of the pixels. Each of the color filters may selectively transmit light of a specific wavelength and may block or absorb light of a different wavelength. In one embodiment, the color filter layer CFL may further include a first light blocking layer (or first light blocking patterns forming the first light blocking layer) surrounding the emission areas of the pixels. The first light blocking layer may be formed separately from the color filters by using a separate light blocking material, or may be formed by overlapping color filters that block lights of different wavelengths.

The color filter layer CFL may absorb some of the light coming from outside of the display device 10 to reduce reflected light. The distortion of color due to reflection of external light may be prevented by the color filter layer CFL.

In one embodiment, the color filter layer CFL may be disposed directly on the touch sensing layer TSU. Accordingly, the display device 10 may not include a separate substrate for the color filter layer CFL, and thus avoid any increase in thickness from the extra substrate.

The light blocking member layer PML may be disposed on the color filter layer CFL. The light blocking member layer PML may include a second light blocking layer (or second light blocking patterns forming the second light blocking layer) disposed to correspond to specific pixels of the display layer DU. For example, the light blocking member layer PML may include the second light blocking layer that is directly adjacent to the emission areas of specific pixels and surrounds the emission areas in plan view.

The light blocking member layer PML may limit the viewing angle of the image displayed by the specific pixels. For example, the display device 10 includes the light blocking member layer PML and thus may control visibility at a specific viewing angle and provide a privacy protection mode to a user.

In some embodiments, the display device 10 may further include an optical device 500 disposed in a component area (e.g., the second display area DA2 or the third display area DA3 of FIGS. 1 and 2). The optical device 500 may emit or receive light in infrared, ultraviolet, and visible light bands. For example, the optical device 500 may be an optical sensor that detects light incident on the display device 10 such as a proximity sensor, an illuminance sensor, and a camera sensor or an image sensor.

FIG. 4 is a plan view illustrating a display area of a display device according to one embodiment. For example, FIG. 4 shows pixel electrodes AE disposed in the display area DA of the display device 10 according to one embodiment and a first light blocking layer BM1 and a second light blocking layer BM2 disposed around the pixel electrodes AE.

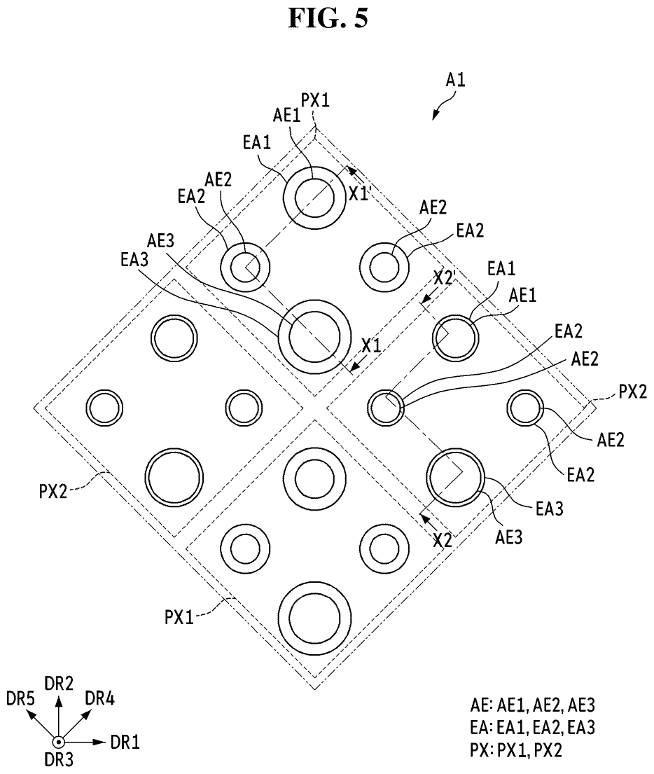

FIG. 5 is a plan view illustrating pixel electrodes according to one embodiment. For example, FIG. 5 shows the pixel electrodes AE disposed in area A1 of FIG. 4 and the emission areas EA where the pixel electrodes AE are disposed.

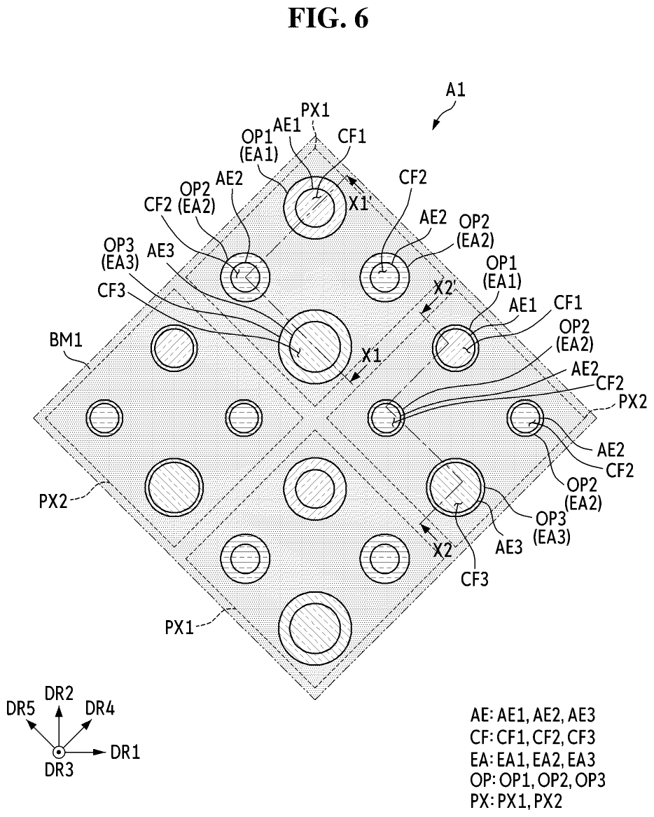

FIG. 6 is a plan view showing pixel electrodes, a first light blocking layer, and color filters according to one embodiment. For example, FIG. 6 shows the pixel electrodes AE disposed in area A1 of FIG. 4 and the first light blocking layer BM1 and the color filters CF disposed around the pixel electrodes AE.

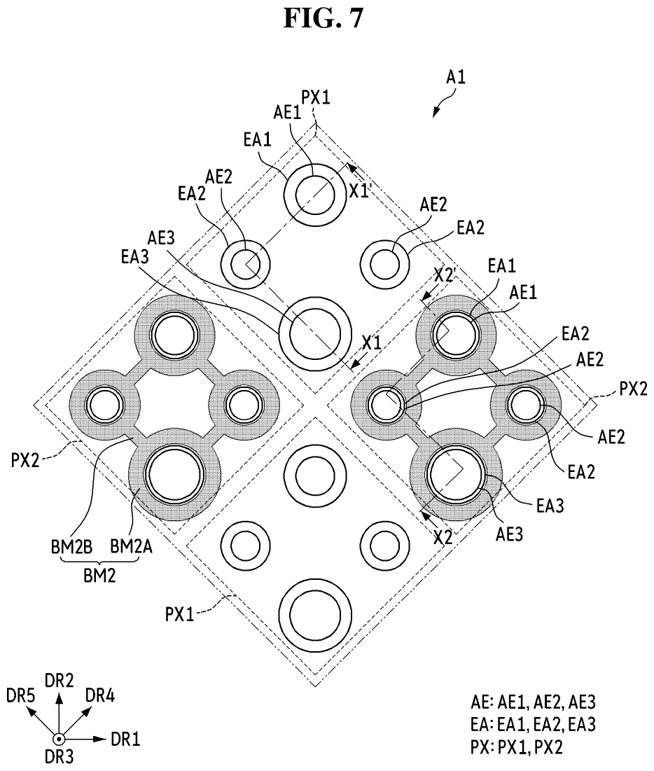

FIG. 7 is a plan view showing pixel electrodes and a second light blocking layer according to one embodiment. For example, FIG. 7 shows the pixel electrodes AE disposed in area A1 of FIG. 4 and the second light blocking layer BM2 disposed around the pixel electrodes AE.

Referring to FIGS. 4 to 7, the display device 10 may include the pixels PX disposed in the display area DA. In one embodiment, the pixels PX may be arranged in a fourth direction DR4 and a fifth direction DR5 between the first direction DR1 and the second direction DR2. In one embodiment, the fourth direction DR4 and the fifth direction DR5 may be diagonal directions with respect to the first direction DR1 and the second direction DR2.

In one embodiment, each of the pixels PX may include a plurality of pixel electrodes AE. For example, each of the pixels PX may include a first pixel electrode AE1, a second pixel electrode AE2, and a third pixel electrode AE3. In one embodiment, one pixel PX may include one first pixel electrode AE1, two second pixel electrodes AE2, and one third pixel electrode AE3. However, embodiments are not limited thereto, and the number of pixel electrodes AE disposed in the pixel PX may be changed.

One pixel electrode AE may be a first electrode, e.g., an anode electrode, of a light emitting element included in each pixel PX. In one embodiment, one pixel PX may include a plurality of light emitting elements and a plurality of pixel circuits respectively electrically connected to the plurality of light emitting elements. Each pixel circuit may be electrically connected to at least one light emitting element. Each pixel circuit and at least one light emitting element connected to the pixel circuit may constitute each sub-pixel.

Each pixel electrode AE shown in FIGS. 4 to 7 may be the entire pixel electrode AE, or a part of the pixel electrode AE exposed by an opening in the pixel defining film. For example, the portions or elements indicated as pixel electrodes AE in FIGS. 4 to 7 may be a part (e.g., a central portion) of each of the pixel electrodes AE not covered by the pixel defining film. On each pixel electrode AE, the light emitting layer of the light emitting element including the pixel electrode AE and the second electrode (e.g., common electrode) may be disposed.

In one embodiment, one pixel PX may include the plurality of light emitting elements that emit lights of different colors. For example, the light emitting element (e.g., first light emitting element) including the first pixel electrode AE1 may emit light of a first color (e.g., red light). The light emitting element (e.g., second light emitting element) including the second pixel electrode AE2 may emit light of a second color (e.g., green light), and the light emitting element (e.g., third light emitting element) including the third pixel electrode AE3 may emit light of a third color (e.g., blue light). Accordingly, the pixel PX may emit any one of the light of the first color, the light of the second color, and the light of the third color, or may emit a mixed light of at least two of the light of the first color, the color of the second color, and the light of the third color. For example, all the light emitting elements included in one pixel PX emit light, so that white light may be emitted from the pixel PX. However, the type, number, and arrangement of the pixel electrodes AE in one pixel PX and the light emitting elements including the same may be changed depending on embodiments.

As shown in FIG. 5, the pixel electrodes AE may be disposed in the emission areas EA of each pixel PX. Each pixel PX may include the plurality of emission areas EA including a first emission area EA1 that emits light of the first color, a second emission area EA2 that emits light of the second color, and a third emission area EA3 that emits light of the third color. In one embodiment, one pixel PX may include one first emission area EA1, two second emission areas EA2, and one third emission area EA3, but embodiments are not limited thereto. The first pixel electrode AE1 may be disposed in the first emission area EA1, the second pixel electrode AE2 may be disposed in the second emission area EA2, and the third pixel electrode AE3 may be disposed in the third emission area EA3. The light emitting element including each pixel electrode AE may be disposed in each emission area EA.

In one embodiment, each emission area EA may include an area where each pixel electrode AE is exposed by an opening formed in the pixel defining film (e.g., the pixel defining film PDL of FIG. 9). Further, each emission area EA, which is an area that is not blocked by the first light blocking layer BM1 and the second light blocking layer BM2, may be a light transmitting area through which light generated from the light emitting element including each pixel electrode AE transmits.

In one embodiment, the pixel electrodes AE may be arranged in a Pentile™ type, e.g., a diamond Pentile™ type. For example, the first pixel electrodes AE1 and the third pixel electrodes AE3 may be spaced apart from each other in the second direction DR2, and may be arranged alternately in the first direction DR1 and the second direction DR2. In each pixel PX, the first pixel electrode AE1 and the third pixel electrode AE3 may be spaced apart from each other in the second direction DR2, and the first pixel electrode AE1 and the third pixel electrode AE3 may be spaced apart from the second pixel electrodes AE2 in the fourth direction DR4 or the fifth direction DR5. The second pixel electrodes AE2 may be repeatedly arranged along the first direction DR1 and the second direction DR2. The second pixel electrodes AE2 and the first pixel electrodes AE1, or the second pixel electrodes AE2 and the third pixel electrodes AE3 may be arranged alternately along the fourth direction DR4 or the fifth direction DR5. However, embodiments are not limited thereto, and the arrangement of the pixel electrodes AE may be variously changed.

In one embodiment, the sizes (e.g., areas) of the first pixel electrode AE1, the second pixel electrode AE2, and the third pixel electrode AE3 may be different from each other. For example, the area of the third pixel electrode AE3 may be larger than those of the first pixel electrode AE1 and the second pixel electrode AE2, and the area of the first pixel electrode AE1 may be larger than that of the second pixel electrode AE2. The intensity of light emitted from each emission area EA may vary depending on the area of the emission area EA where each pixel electrode AE is disposed. Accordingly, the color of the screen displayed on the display device 10 or the electronic device 1 may be controlled by adjusting the area of each pixel electrode AE and the emission area EA including the same. Although FIGS. 4 to 7 show an embodiment in which the third pixel electrode AE3 has the largest area, embodiments are not limited thereto. For example, the size (e.g., area) of the pixel electrode AE and the emission area EA including the same may be freely adjusted depending on the color of the screen required for the display device 10 or the electronic device 1. In addition, the area of the pixel electrode AE and the emission area EA may be related to light efficiency, the lifespan of the light emitting element ED, or the like, and may have a trade-off relation with the reflection by external light. The area of the pixel electrodes AE may be appropriately adjusted in consideration of the above factors.

As shown in FIG. 6, the emission areas EA of the pixels PX may be surrounded by the first light blocking layer BM1. Further, the color filters CF may be disposed in the emission areas EA of the pixels PX. The color filters CF may be disposed on the light emitting element layer (e.g., the light emitting element layer EML of FIG. 3) including the light emitting elements of the pixels PX.

The first light blocking layer BM1 may be entirely disposed in the display area DA, may include the openings OP corresponding to the emission areas EA of the pixels PX, and may be disposed at the periphery of the emission areas EA. For example, in plan view, the first light blocking layer BM1 may include first openings OP1 above the first emission areas EA1, second openings OP2 above the second emission areas EA2, and third openings OP3 above the third emission areas EA3, and may surround the first emission areas EA1, the second emission areas EA2, and the third emission areas EA3. The first light blocking layer BM1 may block the other part (e.g., the non-emission area) of the display area DA except the first emission areas EA1, the second emission areas EA2, and the third emission areas EA3.

The openings OP of the first light blocking layer BM1 may overlap the pixel electrodes AE, or a part of the pixel electrodes AE exposed by the openings of the pixel defining film. The first openings OP1 of the first light blocking layer BM1 may overlap the respective first pixel electrodes AE1. The second openings OP2 of the first light blocking layer BM1 may overlap the respective second pixel electrodes AE2. The third openings OP3 of the first light blocking layer BM1 may overlap the respective third pixel electrodes AE3. In the pixel area where one pixel PX is disposed, one first opening OP1, two second openings OP2, and one third opening OP3 may be formed in the first light blocking layer BM1.

Each of the openings OP of the first light blocking layer BM1 may be greater than each pixel electrode AE (or a part of the pixel electrode AE exposed by the opening of the pixel defining film) in plan view. For example, the area of the first opening OP1 may be larger than the area of the first pixel electrode AE1, the area of the second opening OP2 may be larger than the area of the second pixel electrode AE2, and the area of the third opening OP3 may be larger than the area of the third pixel electrode AE3 in plan view. In one embodiment, the area of the first opening OP1, the area of the second opening OP2, and the area of the third opening OP3 of the first light blocking layer BM1 may be different from each other. For example, the area of the first opening OP1, the area of the second opening OP2, and the area of the third opening OP3 may respectively correspond to the area of the first pixel electrode AE1, the area of the second pixel electrode AE2, and the area of the third pixel electrode AE3. Further, the sizes (e.g., areas) of the first emission area EA1, the second emission area EA2, and the third emission area EA3 may be different and correspond to the area of the first opening OP1, the area of the second opening OP2, and the area of the third opening OP3 of the first light blocking layer BM1.

The display area DA may include at least two types of pixels PX. For example, the display area DA may include first pixels PX1 and second pixels PX2. The light exit angles and/or viewing angles of the first pixels PX1 and the second pixels PX2 may be different. For example, the first pixels PX1 may be the pixels PX that provide a wider range of light exit angles and/or viewing angles, and the second pixels PX2 may be the pixels PX that provide a narrower range of light exit angles and/or viewing angles.

In one embodiment, the first pixels PX1 may be driven only in a first emission mode, and may be turned off or may not emit light in a second emission mode. The second pixels PX2 may be driven in both the first emission mode and the second emission mode. The first emission mode may be a general mode, e.g., a wide viewing angle mode, in which the viewing angle of the image displayed in the display area DA is not limited, and the second lighting mode may be a side viewing angle blocking mode, e.g., a privacy protection mode or a security mode, in which the viewing angle of the image displayed in the display area DA is limited.

In one embodiment, the first pixels PX1 and the second pixels PX2 may be alternately arranged along the fourth direction DR4 and the fifth direction DR5. Further, the first pixels PX1 may be repeatedly arranged along the first direction DR1 and the second direction DR2, and the second pixels PX2 may be repeatedly arranged along the first direction DR1 and the second direction DR2. For example, the first pixels PX1 and the second pixels PX2 may be alternately arranged and uniformly distributed in the entire display area DA. However, embodiments are not limited thereto, and the arrangement shape of the first pixels PX1 and the second pixels PX2 may be variously changed.

In one embodiment, the separation distance (or the size of the openings OP of the first light blocking layer BM1 exposing the emission areas EA of the first pixels PX1) between the openings OP of the first light blocking layer BM1 and the pixel electrodes AE in the first pixels PX1 may be different from the separation distance (or the size of the openings OP of the first light blocking layer BM1 exposing the emission areas EA of the second pixels PX2) between the openings OP of the first light blocking layer BM1 and the pixel electrodes AE in the second pixels PX2. For example, in plan view, the separation distance (or the difference between the diameters of the openings OP of the first light blocking layer BM1 and the diameters of the pixel electrodes AE in the first pixels PX1) between the openings OP of the first light blocking layer BM1 and the pixel electrodes AE in the first pixels PX1 may be greater than the separation distance (or the difference between the diameters of the openings OP of the first light blocking layer BM1 and the diameters of the pixel electrodes AE in the second pixels PX2) between the openings OP of the first light blocking layer BM1 and the pixel electrodes AE in the second pixels PX2. For example, the first light blocking layer BM1 may surround the emission areas EA (or the pixel electrodes AE disposed in the respective emission areas EA and/or the light emitting elements including the same) of the second pixels PXS at a shorter distance than the emission areas EA of the first pixels PX1. Further, the size of the openings OP of the first light blocking layer BM1 above the emission areas EA of the first pixels PX1 may be greater than the size of the openings OP of the first light blocking layer BM1 above the emission areas EA of the second pixels PX2. Accordingly, the light exit angle of light emitted from the second pixels PX2, or the viewing angle of the image displayed by the second pixels PX2 may be narrower than the angle range in which light is emitted from the first pixels PX1, or the viewing angle of the image displayed by the first pixels PX1. In one embodiment, the light exit angle or viewing angle of the second pixels PX2 as well as the size or position of the openings OP of the first light blocking layer BM1 may be controlled (e.g., limited) by the second light blocking layer BM2.

In one embodiment, the size (or the aperture ratio of the first pixels PX1) of the emission areas EA of the first pixels PX1 may be greater than the size (or the aperture ratio of the second pixels PX2) of the emission areas EA of the second pixels PX2. For example, since the first light blocking layer BM1 surrounds the emission areas EA where the pixel electrodes AE of the second pixels PX2 are disposed at a shorter distance, the size (e.g., area) of the emission areas EA of the second pixels PX2 may be reduced compared to the size (e.g., area) of the emission areas EA of the first pixels PX1. In one embodiment, the areas occupied by each first pixel PX1 and each second pixel PX2 in the display area DA may be substantially the same. Accordingly, the size of the non-emission area of the second pixels PX2 may be greater than the size of the non-emission area of the first pixels PX1.

The color filters CF may be disposed in the respective emission area EA, and may be further disposed around the emission areas EA. For example, the color filters CF may cover the pixel electrodes AE disposed in the respective emission areas EA and the light emitting elements including the pixel electrodes AE, and may extend to the peripheries of the emission areas EA.

The color filters CF may include first color filters CF1 disposed in the first emission areas EA1, second color filters CF2 disposed in the second emission areas EA2, and third color filters CF3 disposed in the third emission areas EA3. The color filters CF may contain a colorant such as a dye or a pigment that absorbs light of a wavelength band other than a specific wavelength band. The first color filters CF1 may transmit the light of the first color emitted from the light emitting elements of the first emission areas EA1, and may absorb and/or block light of another color (e.g., light of the second color and light of the third color). For example, each first color filter CF1 may be a red color filter that selectively transmits only red light emitted from the light emitting element disposed in each first emission area EA1. The second color filters CF2 may transmit the light of the second color emitted from the light emitting elements of the second emission areas EA2, and may absorb and/or block light of another color (e.g., the light of the first color and the light of the third color). For example, each second color filter CF2 may be a green color filter that selectively transmits only green light emitted from the light emitting element disposed in each second emission area EA2. The third color filters CF3 may transmit the light of the third color emitted from the light emitting elements of the third emission areas EA3, and may absorb and/or block light of another color (e.g., the light of the first color and the light of the second color). For example, each third color filter CF3 may be a blue color filter that selectively transmits only blue light emitted from the light emitting element disposed in each third emission area EA3.

The color filters CF may be formed as individual patterns corresponding to the respective emission areas EA, or may be formed entirely in the display area DA. For example, each first color filter CF1 may be formed as an individual pattern that covers each first emission area EA1 and the periphery of the first emission area EA1, each second color filter CF2 may be formed as an individual pattern that covers each second emission area EA2 and the periphery of the second emission area EA2, and each third color filter CF3 may be formed as an individual pattern that covers each third emission area EA3 and the periphery of the third emission area EA3. Alternatively, the first color filter CF1 may include openings formed entirely in the display area DA and corresponding to the second emission areas EA2 and the third emission areas EA3, the second color filter CF2 may include openings formed entirely in the display area DA and corresponding to the first emission areas EA1 and the third emission areas EA3, and the third color filter CF3 may include openings formed entirely in the display area DA and corresponding to the first emission areas EA1 and the second emission areas EA2.

In one embodiment, the first light blocking layer BM1 may be formed as a light blocking pattern separate from the color filters CF, or may be formed as a part of the color filters CF. For example, the display device 10 may include the first light blocking layer BM1 formed as a light blocking pattern separate from the color filters CF, or may include the first light blocking layer BM1 formed by overlapping the color filters CF that block lights of different colors in the non-emission areas around the emission areas EA.

In one embodiment, the first light blocking layer BM1 and the color filters CF may be disposed on the display layer DU. For example, the first light blocking layer BM1 and the color filters CF may be disposed in the color filter layer CFL disposed on the touch sensing layer TSU of FIG. 3. Since the color filters CF and the first light blocking layer BM1 are disposed on the display layer DU, the intensity of reflected light due to external light may be reduced.

As shown in FIG. 7, the second light blocking layer BM2 may be disposed in some pixels PX among the pixels PX disposed in the display area DA. For example, the second pixels PX2 may include the second light blocking layer BM2. The second light blocking layer BM2 may not be disposed in the first pixels PX1.

The second light blocking layer BM2 may surround the emission areas EA of some pixels PX among the pixels PX. For example, the second light blocking layer BM2 may be disposed in the non-emission area of the second pixels PX2, and may surround the emission areas EA of the second pixels PX2. For example, the second light blocking layer BM2 may surround the first emission areas EA1, the second emission areas EA2, and the third emission areas EA3 of the second pixels PX2.

In one embodiment, the second light blocking layer BM2 may be disposed on the first light blocking layer BM1 and the color filters CF. For example, the second light blocking layer BM2 may be disposed in the light blocking member layer PML disposed on the color filter layer CFL of FIG. 3. Since the second light blocking layer BM2 is disposed on the color filter layer CFL, the light exit angle or viewing angle of the second pixels PX2 may be adjusted or limited.

The light exit angle or viewing angle of the second pixels PX2 may be adjusted or changed by at least one of the size of the openings OP of the first light blocking layer BM1, the separation distance between and the first light blocking layer BM1 and the pixel electrodes AE of the second pixels PX2, the presence/absence of the second light blocking layer BM2, or the separation distance between the second light blocking layer BM2 and the pixel electrodes AE of the second pixels PX2. For example, by disposing the second light blocking layer BM2 on the second pixels PX2, the light exit angle or viewing angle of the second pixels PX2 may be further reduced.

In one embodiment, the second light blocking layer BM2 disposed in one second pixel PX2 may be formed as one pattern. For example, the second light blocking layer BM2 disposed in one second pixel PX2 may include first portions BM2A surrounding the first emission area EA1, the second emission area EA2, and the third emission area EA3, and second portions BM2B that connect the first portions BM2A. The first portions BM2A of the second light blocking layer BM2 may include respective openings corresponding to the respective emission areas EA, and may have a shape (e.g., a ring shape) surrounding the emission areas EA. The second portions BM2B of the second light blocking layer BM2 may be disposed between the first portions BM2A, and may be formed integrally with the first portions BM2A. Accordingly, in a pixel process for forming the pixels PX, the second light blocking layer BM2 may be prevented from moving away from a determined position or being peeled off, and the second light blocking layer BM2 may be more stably formed.

As described above, the display device 10 according to one embodiment may include the first pixels PX1 where the second light blocking layer BM2 is not disposed and the second pixels PX2 where the second light blocking layer BM2 is disposed, and the side visibility may be adjusted depending on the emission mode. Depending on the viewing angle of the display device 10, patterns (e.g., light blocking pattern disposed in each second pixel PX2) of the second light blocking layer BM2 may partially cover the pixel electrode AE, and may block the emission of light at a specific viewing angle.

For example, in a state where the side visibility is not limited, which is the first emission mode of the display device 10, both the first pixels PX1 and the second pixels PX2 may emit light. Since both the first pixels PX1 and the second pixels PX2 emit light in the first emission mode, the display device 10 may provide a wide viewing angle. For example, regardless of the direction from which the display device 10 is viewed, the light emitted from at least the first pixels PX1 may be visually recognized by the user.

On the other hand, if it is desired to limit the side visibility, which is the second emission mode of the display device 10, the first pixels PX1 may not emit light, and only the second pixels PX2 may emit light. Since only the second pixels PX2 emit light in the second emission mode, the lights emitted from the openings OP of the first light blocking layer BM1 may be blocked by the second light blocking layer BM2 at a specific viewing angle. Since the first pixels PX1 do not emit light, the image of the display device 10 in the second emission mode may be visually recognized only by the user looking from the front of the display area DA, and may not be visually recognized by the user looking at a specific viewing angle or from the side. Accordingly, the display device 10 may provide a side viewing angle blocking mode, e.g., a privacy protection mode, to the user.

In the second emission mode of the display device 10, a light leakage phenomenon of light emitted may occur depending on a degree in which the pixel electrodes AE of the second pixels PX2 are blocked by the second light blocking layer BM2. However, in the display device 10 according to one embodiment, the light blocking patterns of the second light blocking layer BM2 may have a shape corresponding to the shape of the pixel electrodes AE and may be disposed to surround the emission areas EA where the pixel electrodes AE are disposed. In the second emission mode, the degree in which the pixel electrodes AE of the second pixels PX2 are blocked may be uniform at all viewing angles when viewing the display device 10, and the light leakage phenomenon of light emitted from the light emitting element including the specific pixel electrode AE may be prevented.

Further, in the display device 10 according to one embodiment, the light blocking members of the second light blocking layer BM2 are disposed to correspond to the pixel electrodes AE of the second pixels PX2, and thus may be disposed so as not to invade other adjacent pixels, e.g., the first pixels PX1. Accordingly, in the first emission mode, the light blocking members of the second light blocking layer BM2 may not block the light emitted from the emission areas EA of the first pixels PX1.

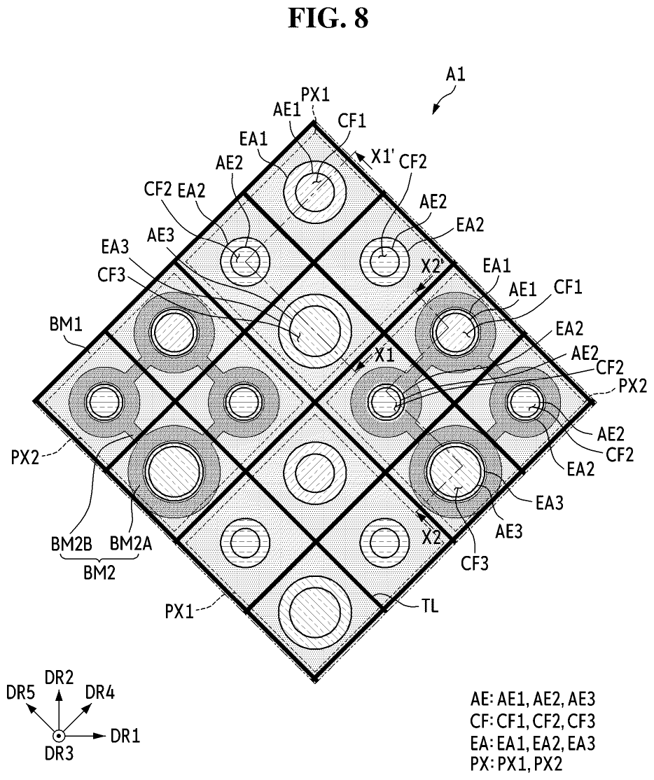

FIG. 8 is a plan view illustrating a display area of a display device according to one embodiment. For example, FIG. 8 shows a touch electrode TL together with the pixel electrodes AE, the first light blocking layer BM1, the color filters CF, and the second light blocking layer BM2 that are disposed in area A1 of FIG. 4.

Referring to FIG. 8 in addition to FIGS. 4 to 7, the display device 10 may further include the touch electrodes TL disposed between the pixel electrodes AE. Although FIG. 8 shows the approximate shape of the touch electrode TL disposed in area A1 of FIG. 4, a plurality of touch electrodes TL may be disposed in the display area DA. For example, when the display device 10 includes a mutual capacitance type touch sensor, the plurality of touch electrodes TL including driving electrodes and sensing electrodes may be disposed in the display area DA.

In one embodiment, the touch electrodes TL may be formed as mesh-shaped patterns including openings above the emission areas EA of the pixels PX. For example, each touch electrode TL or each of a plurality of electrode cells constituting the touch electrode TL may be a mesh-shaped pattern formed of thin lines respectively extending in the fourth direction DR4 or the fifth direction DR5 and overlapping the first light blocking layer BM1.

In one embodiment, the resolution of the pixels PX and the resolution of the touch electrodes TL may be different. For example, each touch electrode TL may be disposed in the area where the plurality of pixels PX are disposed. For example, the touch electrode TL shown in FIG. 8 may be one touch electrode TL disposed in area A1 of FIG. 4 or one electrode cell forming the touch electrode TL. The shape, number, resolution, and/or structure of the touch electrodes TL may be variously changed depending on embodiments. In one embodiment, the touch electrodes TL may be connected or extended in a desired shape or direction through respective bridge patterns.

In one embodiment, the touch electrodes TL may be disposed on the display layer DU. For example, the touch electrodes TL may be disposed in the touch sensing layer TSU of FIG. 3. A touch input by a user may be sensed in the display area DA by the touch electrodes TL.

FIG. 9 is a cross-sectional view illustrating a display device according to one embodiment. For example, FIG. 9 shows a portion of the display device 10 corresponding to the cross section of the first pixel PX1 taken along line X1-X1′ of FIGS. 4 to 8.

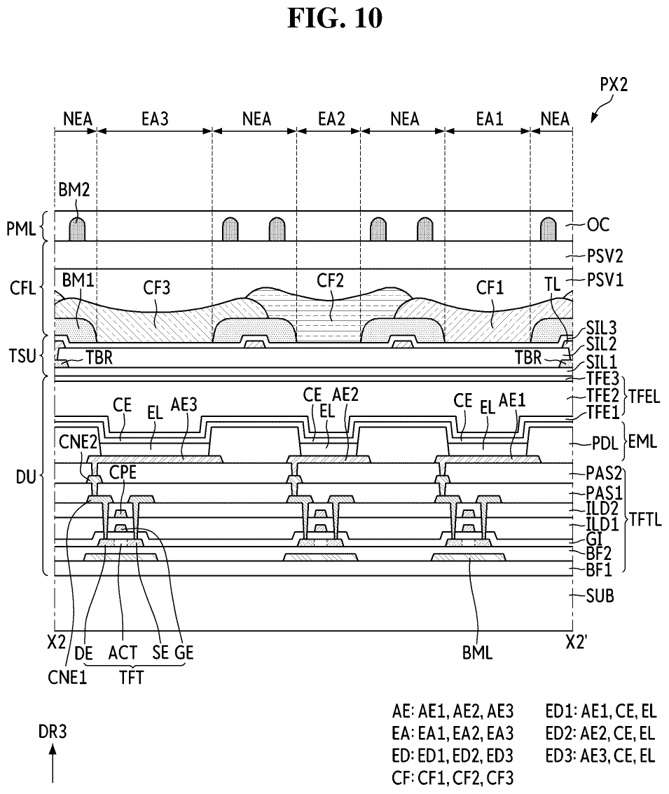

FIG. 10 is a cross-sectional view showing a display device according to one embodiment. For example, FIG. 10 shows a portion of the display device 10 corresponding to the cross section of the second pixel PX2 taken along line X2-X2′ of FIGS. 4 to 8.

Referring to FIGS. 9 and 10 in addition to FIGS. 1 to 8, the display panel 100 of the display device 10 according to one embodiment may include the display layer DU, the touch sensing layer TSU, the color filter layer CFL, and the light blocking member layer PML. The display layer DU may include the substrate SUB, the thin film transistor layer TFTL, the light emitting element layer EML, and the encapsulation layer TFEL. The touch sensing layer TSU may include the touch electrodes TL and bridge patterns TBR. The color filter layer CFL may include the first light blocking layer BM1 and the color filters CF. The light blocking member layer PML may include the second light blocking layer BM2.

The substrate SUB may be a base substrate or a base member. In one embodiment, the substrate SUB may be a flexible substrate which can be bent, folded or rolled, but is not limited thereto.

The thin film transistor layer TFTL may include a first buffer layer BF1, a lower metal layer BML, a second buffer layer BF2, a thin film transistor TFT, a gate insulating layer GI, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2. However, embodiments are not limited thereto, and the number or type of conductive layers and insulating layers forming the thin film transistor layer TFTL, and/or the structure or type of the thin film transistor TFT may be variously changed depending on embodiments.

The first buffer layer BF1 may be disposed on the substrate SUB. The first buffer layer BF1 may include an inorganic film capable of preventing penetration of air or moisture. For example, the first buffer layer BF1 may include a plurality of inorganic films stacked on one another.

The lower metal layer BML may be disposed on the first buffer layer BF1. In one embodiment, the lower metal layer BML may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

The second buffer layer BF2 may cover the first buffer layer BF1 and the lower metal layer BML. The second buffer layer BF2 may include an inorganic film capable of preventing penetration of air or moisture. For example, the second buffer layer BF2 may include a plurality of inorganic films stacked on one another.

The thin film transistor TFT may be disposed on the second buffer layer BF2, and may be provided to each of the pixel circuits (e.g., pixel circuits of sub-pixels) included in each pixel PX. FIGS. 9 and 10 show the approximate shape of one thin film transistor TFT (e.g., the thin film transistor TFT electrically connected to the first light emitting element ED1, the second light emitting element ED2, or the third light emitting element ED3) among the thin film transistors that may be provided to the respective pixel circuits (e.g., pixel circuits of sub-pixels) of the first pixel PX1 and the second pixel PX2. Each thin film transistor TFT shown in FIGS. 9 and 10 may be a switching transistor or a driving transistor constituting each pixel circuit. The thin film transistor TFT may include a semiconductor layer ACT, a source electrode SE, a drain electrode DE, and a gate electrode GE.

The semiconductor layer ACT may be disposed on the second buffer layer BF2. The semiconductor layer ACT may overlap the lower metal layer BML and the gate electrode GE in the thickness direction, and may be insulated from the gate electrode GE by the gate insulating layer GI. A part of the semiconductor layer ACT may become conductive to form the source electrode SE (or source region) and the drain electrode DE (or drain region).

The gate electrode GE may be disposed on the gate insulating layer GI. The gate electrode GE may overlap the semiconductor layer ACT with the gate insulating layer GI interposed therebetween.

The gate insulating layer GI may be disposed on the semiconductor layer ACT.

For example, the gate insulating layer GI may cover the semiconductor layer ACT and the second buffer layer BF2, and may be disposed between the semiconductor layer ACT and the gate electrode GE. The gate insulating layer GI may include a contact hole through which the first connection electrode CNE1 passes.

The first interlayer insulating layer ILD1 may cover the gate electrode GE and the gate insulating layer GI. The first interlayer insulating layer ILD1 may include a contact hole through which the first connection electrode CNE1 passes. The contact hole of the first interlayer insulating layer ILD1 may be connected to the contact hole of the gate insulating layer GI and the contact hole of the second interlayer insulating layer ILD2.

The capacitor electrode CPE may be disposed on the first interlayer insulating layer ILD1. The capacitor electrode CPE may overlap the gate electrode GE in the thickness direction. The capacitor electrode CPE and the gate electrode GE may form a capacitance. For example, a storage capacitor of each pixel circuit may be formed by the capacitor electrode CPE and the gate electrode GE.

The second interlayer insulating layer ILD2 may cover the capacitor electrode CPE and the first interlayer insulating layer ILD1. The second interlayer insulating layer ILD2 may include a contact hole through which the first connection electrode CNE1 passes. The contact hole of the second interlayer insulating layer ILD2 may be connected to the contact hole of the first interlayer insulating layer ILD1 and the contact hole of the gate insulating layer GI.

The first connection electrode CNE1 may be disposed on the second interlayer insulating layer ILD2. The first connection electrode CNE1 may electrically connect the drain electrode DE of the thin film transistor TFT to the second connection electrode CNE2. When the type of the thin film transistor TFT and/or the structure of the pixel circuit is changed, the first connection electrode CNE1 may electrically connect the source electrode SE of the thin film transistor TFT to the second connection electrode CNE2. The first connection electrode CNE1 may be in contact with and/or connected to the drain electrode DE of the thin film transistor TFT through a contact hole formed in the second interlayer insulating layer ILD2, the first interlayer insulating layer ILD1, and the gate insulating layer GI.

The first passivation layer PAS1 may cover the first connection electrode CNE1 and the second interlayer insulating layer ILD2. The first passivation layer PAS1 may protect the thin film transistor TFT. The first passivation layer PAS1 may include a contact hole through which the second connection electrode CNE2 passes.

The second connection electrode CNE2 may be disposed on the first passivation layer PAS1. The second connection electrode CNE2 may electrically connect the first connection electrode CNE1 to a pixel electrode AE of the light emitting element ED. The second connection electrode CNE2 may be in contact with and/or connected to the first connection electrode CNE1 through a contact hole formed in the first passivation layer PAS1. Further, the second connection electrode CNE2 may be in contact with and/or connected to the pixel electrode AE of the light emitting element ED through a contact hole formed in the second passivation layer PAS2. In another embodiment, the thin film transistor layer TFTL may not include the second connection electrode CNE2, and the pixel electrode AE of the light emitting element ED may be directly connected to the first connection electrode CNE1 (or one electrode of the thin film transistor TFT).

The second passivation layer PAS2 may cover the second connection electrode CNE2 and the first passivation layer PAS1. The second passivation layer PAS2 may include a contact hole through which the pixel electrode AE of the light emitting element ED passes. In another embodiment, the thin film transistor layer TFTL may not include the second connection electrode CNE2 and the second passivation layer PAS2, and the pixel electrode AE of the light emitting element ED may be disposed on the first passivation layer PAS1.

The light emitting element layer EML may be disposed on the thin film transistor layer TFTL. The light emitting element layer EML may include the light emitting element ED and the pixel defining film (also referred to as “pixel defining layer”) PDL. The light emitting element ED may include the pixel electrode AE (e.g., the first electrode or the anode electrode of the light emitting element ED), a light emitting layer EL, and a common electrode CE (e.g., the second electrode or the cathode electrode of the light emitting element ED). For example, the first light emitting element ED1 disposed in each first emission area EA1 may include the first pixel electrode AE1, and the light emitting layer EL and the common electrode CE that are sequentially disposed on the first pixel electrode AE1. The second light emitting element ED2 disposed in each second emission area EA2 may include the second pixel electrode AE2, and the light emitting layer EL and the common electrode CE that are sequentially disposed on the second pixel electrode AE2. The third light emitting element ED3 disposed in each third emission area EA3 may include the third pixel electrode AE3, and the light emitting layer EL and the common electrode CE that are sequentially disposed on the third pixel electrode AE3.

The pixel electrode AE may be disposed on the second passivation layer PAS2. Different pixel electrodes AE may be disposed in the respective emission areas EA corresponding to different openings among the openings of the pixel defining film PDL. For example, the first pixel electrode AE1, the second pixel electrode AE2, and the third pixel electrode AE3 of the first pixel PX1 may be disposed in the first emission area EA1, the second emission area EA2, and the third emission area EA3 of the first pixel PX1, respectively, and the first pixel electrode AE1, the second pixel electrode AE2, and the third pixel electrode AE3 of the second pixel PX2 may be disposed in the first emission area EA1, the second emission area EA2, and the third emission area EA3 of the second pixel PX2, respectively.

The pixel electrode AE may be electrically connected to one electrode of the thin film transistor TFT. For example, the pixel electrode AE may be electrically connected to the drain electrode DE of the thin film transistor TFT through the first connection electrode CNE1 and the second connection electrode CNE2.

The light emitting layer EL may be disposed on the pixel electrode AE. In one embodiment, the light emitting layer EL may be an organic light emitting layer made of an organic material, but is not limited thereto.

In one embodiment, the light emitting layers EL of the first light emitting element ED1, the second light emitting element ED2, and the third light emitting element ED3 may emit lights of different colors. For example, the light emitting layer EL of the first light emitting element ED1 may emit light of the first color, e.g., red light, the light emitting layer EL of the second light emitting element ED2 may emit light of the second color, e.g., green light, and the light emitting layer EL of the third light emitting element ED3 may emit light of the third color, e.g., blue light.

However, the embodiments are not limited thereto. For example, in another embodiment, the light emitting layer EL of the light emitting elements ED may be formed as one common layer disposed on the different pixel electrodes AE and the pixel defining film PDL, and the light emitting layer EL disposed on different pixel electrodes AE may emit light of the same color. In this case, the display device 10 may further include a color adjustment layer (e.g., color conversion layer including wavelength conversion patterns and/or color adjustment layer including the color filters CF) disposed on the light emitting elements ED.

The common electrode CE may be disposed on the light emitting layer EL of each of the light emitting elements ED. In one embodiment, the common electrode CE may be formed as one common layer disposed entirely in the display area DA, and the light emitting elements ED of the pixels PX may share one common electrode CE.

The common electrode CE may receive a common voltage (e.g., second pixel voltage or cathode voltage). When the pixel electrode AE receives the first pixel voltage through the thin film transistor TFT and the common electrode CE receives the common voltage, the light emitting layer EL may emit light with a brightness corresponding to the data voltage.

The pixel defining film PDL may include openings corresponding to the emission areas EA and may be disposed on a part of the pixel electrodes AE and the second passivation layer PAS2. The openings of the pixel defining film PDL may define the respective emission areas EA, and may partially expose the pixel electrodes AE in the emission areas EA. The pixel defining film PDL may overlap the first light blocking layer BM1 and the second light blocking layer BM2.

The respective light emitting layers EL may be disposed on the exposed portions of the pixel electrodes AE. Accordingly, each light emitting element ED may be disposed and/or formed in each emission area EA. In one embodiment, the openings of the pixel defining film PDL may define the first emission area EA1, the second emission area EA2, and the third emission area EA3 of different sizes.

In one embodiment, the pixel defining film PDL may include a light absorbing material to prevent light reflection. For example, the pixel defining film PDL may include a polyimide (PI)-based binder and a pigment in which red, green, and blue colors are mixed. Alternatively, the pixel defining film PDL may include a cardo-based binder resin and a mixture of a lactam black pigment and a blue pigment. Alternatively, the pixel defining film PDL may include carbon black.

The encapsulation layer TFEL may be disposed on the common electrode CE to cover the light emitting elements ED. The encapsulation layer TFEL may include at least one inorganic film to prevent oxygen or moisture from penetrating into the light emitting element layer EML. The encapsulation layer TFEL may include at least one organic film to protect the light emitting element layer EML from foreign matters such as dust.

In one embodiment, the encapsulation layer TFEL may include a first encapsulation layer TFE1, a second encapsulation layer TFE2, and a third encapsulation layer TFE3 that are sequentially disposed on the light emitting elements ED. The first encapsulation layer TFE1 and the third encapsulation layer TFE3 may be inorganic encapsulation layers, and the second encapsulation layer TFE2 disposed between the first encapsulation layer TFEL and the third encapsulation layer TFE3 may be an organic encapsulation layer.

Each of the first encapsulation layer TFE1 and the third encapsulation layer TFE3 may include an inorganic insulating material. For example, each of the first encapsulation layer TFE1 and the third encapsulation layer TFE3 may include aluminum oxide, titanium oxide, tantalum oxide, hafnium oxide, zinc oxide, silicon oxide, silicon nitride, silicon oxynitride and/or another inorganic insulating material.

The second encapsulation layer TFE2 may include an organic insulating material. For example, the second encapsulation layer TFE2 may include a polymer-based organic insulating material such as acrylic resin, epoxy resin, polyimide, or polyethylene, or may include another organic insulating material. The second encapsulation layer TFE2 may be formed by curing a monomer or applying a polymer.

The touch sensing layer TSU may be disposed on the encapsulation layer TFEL. The touch sensing layer TSU may include a first insulating layer SIL1, a second insulating layer SIL2, the touch electrode TL, and a third insulating layer SIL3. In one embodiment, the touch sensing layer TSU may further include bridge patterns TBR for connecting the touch electrodes TL disposed in the display area DA, or the electrode cells forming the touch electrodes TL in a desired form and/or structure. Each bridge pattern TBR may overlap a portion of at least one touch electrode TL, and be electrically connected to the touch electrode TL.

The first insulating layer SIL1 may be disposed on the encapsulation layer TFEL. The first insulating layer SIL1 may have an insulating function and an optical function. In one embodiment, the first insulating layer SIL1 may include at least one inorganic film. Optionally, the first insulating layer SIL1 may be omitted.

The bridge pattern TBR may be disposed on the first insulating layer SIL1. The position of the bridge pattern TBR may vary according to embodiments. For example, the touch electrode TL and the bridge pattern TBR may be disposed in different layers of the touch sensing layer TSU, and the positions of the touch electrode TL and the bridge pattern TBR may be reversed. For one example, one of the touch electrode TL and the bridge pattern TBR may be disposed on the first insulating layer SIL1, and the other one of the touch electrode TL and the bridge pattern TBR may be disposed on the second insulating layer SIL2.

The second insulating layer SIL2 may be disposed on the bridge pattern TBR. For example, the second insulating layer SIL2 may cover the bridge pattern TBR and the first insulating layer SIL1, and may be disposed between the touch electrode TL and the bridge pattern TBR. The second insulating layer SIL2 may include a contact hole through which the touch electrode TL (or the bridge pattern TBR) passes at a portion where the touch electrode TL and the bridge pattern TBR are connected.

The second insulating layer SIL2 may have an insulating function and an optical function. In one embodiment, the second insulating layer SIL2 may be an inorganic film containing at least one of a silicon nitride layer, a silicon oxynitride layer, a silicon oxide layer, a titanium oxide layer, or an aluminum oxide layer.

The touch electrode TL (or a part of the touch electrodes TL in the display area DA) may be disposed on the second insulating layer SIL2. The touch electrode TL may include a conductive material and may be formed as a single layer or multiple layers. For example, the touch electrode TL may be formed as a single layer containing molybdenum (Mo), titanium (Ti), copper (Cu), aluminum (Al), or indium tin oxide (ITO), or may be formed to have a stacked structure (Ti/Al/Ti) of aluminum and titanium, a stacked structure (ITO/Al/ITO) of aluminum and ITO, an Ag—Pd—Cu (APC) alloy, or a stacked structure (ITO/APC/ITO) of APC alloy and ITO.

In one embodiment, the touch electrode TL may not overlap the pixel electrodes AE. For example, the touch electrode TL may be disposed in a non-emission area NEA located around the emission areas EA. The touch electrode TL may overlap the pixel defining film PDL and the first light blocking layer BM1.

In one embodiment, the first light blocking layer BM1 may have a width enough to completely cover the touch electrode TL, and the gap between the edge of the first light blocking layer BM1 and the touch electrode TL may be defined. In one embodiment, the line width of the thin lines forming the touch electrode TL may be within a range of 4 μm to 6 μm, and the gap between the touch electrode TL and the edge of the first light blocking layer BM1 may be within a range of 5 μm to 7 μm. The touch electrode TL may be disposed such that the center thereof is substantially side by side with the center of the first light blocking layer BM1, and the distance from both sides of the touch electrode TL to the edge of the first light blocking layer BM1 may be substantially constant.

The third insulating layer SIL3 may be disposed on the touch electrode TL. For example, the third insulating layer SIL3 may cover the touch electrode TL and the second insulating layer SIL2. The third insulating layer SIL3 may have an insulating function and an optical function. In one embodiment, the third insulating layer SIL3 may include a material exemplified as the material of the second insulating layer SIL2.

The color filter layer CFL may be disposed on the touch sensing layer TSU. The color filter layer CFL may include the first light blocking layer BM1, the color filters CF, and at least one passivation layer. For example, the color filter layer CFL may include the first light blocking layer BM1, the color filters CF, the first passivation layer PSV1, and the second passivation layer PSV2.

The first light blocking layer BM1 may be disposed on the touch sensing layer TSU. The first light blocking layer BM1 may cover the touch electrode TL, and may include the openings OP above the pixel electrodes AE. For example, the first light blocking layer BM1 may include the first opening OP1 disposed in each first emission area EA1 to be above the first pixel electrode AE1, the second opening OP2 disposed in each second emission area EA2 to be above the second pixel electrode AE2, and the third opening OP3 disposed in each third emission area EA3 to be above the third pixel electrode AE3. The first light blocking layer BM1 may include a light blocking material (e.g., a light absorbing material) such as a black matrix material.

In one embodiment, the first light blocking layer BM1 may have different-sized openings in the first pixel PX1 and the second pixel PX2. For example, the area (or width) of the first opening OP1, the second opening OP2, and the third opening OP3 that are disposed in the first emission area EA1, the second emission area EA2, and the third emission area EA3 of the first pixel PX1 may be greater than the area (or width) of the first opening OP1, the second opening OP2, and the third opening OP3 that are disposed in the first emission area EA1, the second emission area EA2, and the third emission area EA3 of the second pixel PX2, respectively.

The color filters CF may be disposed on the touch sensing layer TSU and the first light blocking layer BM1. The color filters CF may be disposed in the respective emission areas EA and overlap the respective light emitting elements ED. In one embodiment, the color filters CF may also be disposed around the respective emission areas EA, and at least two color filters CF may overlap each other between the emission areas EA.

The first color filter CF1 may be disposed in the first emission area EA1 and overlap the first light emitting element ED1. In one embodiment, the edge portion of the first color filter CF1 may be disposed around the first emission area EA1 and overlap a part of the first light blocking layer BM1. For example, in plan view, the edge portion of the first color filter CF1 may surround the first emission area EA1, and may be disposed on a part of the first light blocking layer BM1.

The second color filter CF2 may be disposed in the second emission area EA2 and overlap the second light emitting element ED2. In one embodiment, the edge portion of the second color filter CF2 may be disposed around the second emission area EA2 and overlap a part of the first light blocking layer BM1. For example, in plan view, the edge portion of the second color filter CF2 may surround the second emission area EA2, and may be disposed on a part of the first light blocking layer BM1.

The third color filter CF3 may be disposed in the third emission area EA3 and overlap the third light emitting element ED3. In one embodiment, the edge portion of the third color filter CF3 may be disposed around the third emission area EA3 and overlap a part of the first light blocking layer BM1. For example, in plan view, the edge portion of the third color filter CF3 may surround the third emission area EA3, and may be disposed on a part of the first light blocking layer BM1.

The first passivation layer PSV1 and the second passivation layer PSV2 may be sequentially disposed on the first light blocking layer BM1 and the color filters CF. The first passivation layer PSV1 and the second passivation layer PSV2 may be entirely disposed in the display area DA, thereby flattening the stepped portion caused by the color filters CF and the first light blocking layer BM1.

The first passivation layer PSV1 and the second passivation layer PSV2 may be light transmissive layers. For example, the first passivation layer PSV1 and the second passivation layer PSV2 may include a colorless light transmissive organic material such as an acrylic resin.

The light blocking member layer PML may be disposed on the color filter layer CFL. The light blocking member layer PML may include the second light blocking layer BM2 and an overcoat layer OC.

The second light blocking layer BM2 may be disposed on the color filter layer CFL. The second light blocking layer BM2 may include a light blocking material such as a black matrix material. The material of the first light blocking layer BM1 and the material of the second light blocking layer BM2 may be the same or different.

The second light blocking layer BM2 may be disposed on a subgroup of the pixels. A “subgroup” of pixels, as used herein, refers to less than all the pixels. For example, the second light blocking layer BM2 may not be disposed in the first pixels PX1, and may be disposed only in the second pixels PX2. The second light blocking layer BM2 may surround the emission areas EA of the second pixels PX2 in plan view. In one embodiment, the second light blocking layer BM2 may be opened wider than the openings OP of the first light blocking layer BM1, but the present disclosure is not limited thereto. The size, shape, and/or position of the second light blocking layer BM2 may be adjusted or changed depending on the target viewing angle range of the second pixels PX2.

The overcoat layer OC may be disposed on the second light blocking layer BM2. The overcoat layer OC may cover the color filter layer CFL and the second light blocking layer BM2.

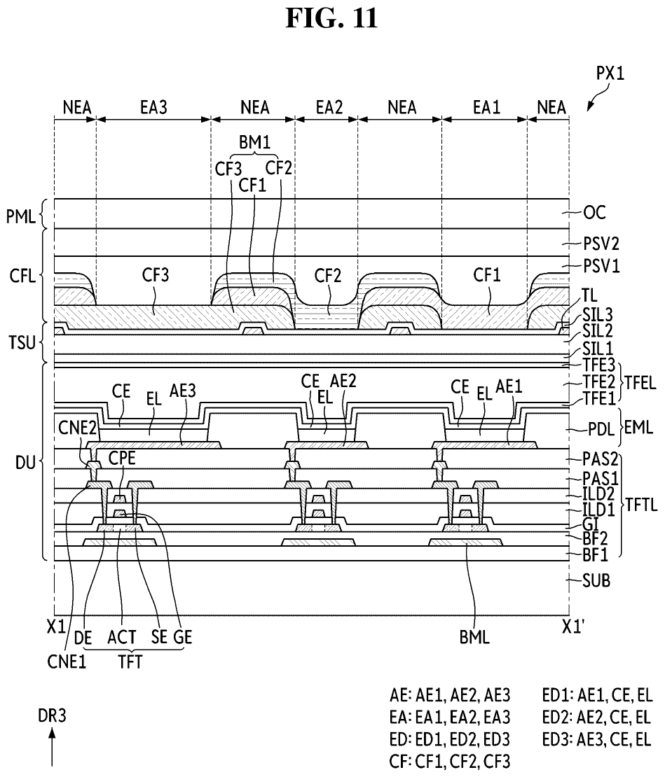

FIG. 11 is a cross-sectional view showing a display device according to one embodiment. For example, FIG. 11 shows a portion of the display device 10 corresponding to the cross section of the first pixel PX1 taken along line X1-X1′ of FIGS. 4 to 8.

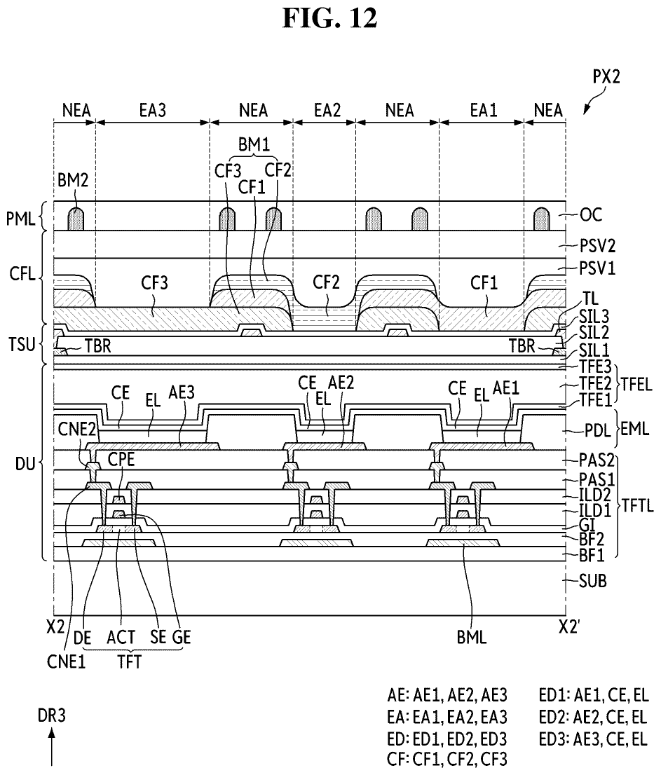

FIG. 12 is a cross-sectional view illustrating a display device according to one embodiment. For example, FIG. 12 shows a portion of the display device 10 corresponding to the cross section of the second pixel PX2 taken along line X2-X2′ of FIGS. 4 to 8.

FIGS. 11 and 12 show an embodiment different from the embodiment of FIGS. 9 and 10 in relation to the first light blocking layer BM1. In describing the following embodiments, components substantially identical or similar to those of at least one embodiment described above are designated with the same reference numerals, and redundant descriptions will be omitted.

Referring to FIGS. 11 and 12 in addition to FIGS. 1 to 10, the display device 10 according to one embodiment may include the first light blocking layer BM1 formed by overlapping the color filters CF of different colors. For example, the display device 10 according to one embodiment may not include a separate first light blocking layer BM1, e.g., the first light blocking layer BM1 of FIGS. 9 and 10, that is formed separately from the color filters CF and includes a light blocking material. The display device 10 may include, instead of the first light blocking layer BM1 of FIGS. 9 and 10, the first light blocking layer BM1 including the color filters CF arranged to overlap each other in the non-emission area NEA around the emission areas EA. The non-emission area NEA may be the part of the display area DA other than the emission areas EA. For example, the non-emission area NEA may be located around the emission areas EA, and may be disposed at the periphery of each of the emission areas EA and between the emission areas EA.

The first light blocking layer BM1 according to one embodiment may include the first color filter CF1, the second color filter CF2, and the third color filter CF3 overlapping each other in the non-emission area NEA. For example, the first color filter CF1 may be disposed in the non-emission area NEA and the first emission areas EA1 of the pixels PX, the second color filter CF2 may be disposed in the non-emission area NEA and the second emission areas EA2 of the pixels PX, and the third color filter CF3 may be disposed in the non-emission area NEA and the third emission areas EA3 of the pixels PX. The first light blocking layer BM1 may be formed of a part of each of the first color filter CF1, the second color filter CF2, and the third color filter CF3. For example, in the non-emission area NEA, the first color filter CF1, the second color filter CF2, and the third color filter CF3 may overlap in the thickness direction (e.g., the third direction DR3) of the display panel 100 to form the first light blocking layer BM1.

In one embodiment, among the first color filter CF1, the second color filter CF2, and the third color filter CF3, the third color filter CF3 may be disposed at the lowermost portion, and the second color filter CF2 may be disposed at the uppermost portion. For example, the color filters CF of the color filter layer CFL may be sequentially arranged or formed on the touch sensing layer TSU in the order of the third color filter CF3, the first color filter CF1, and the second color filter CF2.

However, embodiments are not limited thereto, and the arrangement order of the color filters CF may vary. For example, in another embodiment, the color filters CF may be arranged or formed in the order of the first color filter CF1, the third color filter CF3, and the second color filter CF2.

In one embodiment, among the combinations of the color filters CF, the combination of the color filters CF with a higher light blocking effect (e.g., light blocking rate for visible light emitted from the pixels PX) may be disposed at the lower part of the first light blocking layer BM1. For example, the first color filter CF1 and the third color filter CF3, which selectively transmit red light and blue light, respectively, and absorb or block light of other colors, may be disposed under the second color filter CF2. Accordingly, the first light blocking layer BM1 with an excellent light blocking effect may be formed by utilizing the color filters CF without forming a separate light blocking pattern.

In accordance with the above-described embodiment, the process of forming the first light blocking layer BM1 using a separate light blocking material may be omitted, and the first light blocking layer BM1 may be formed in the non-emission area NEA by utilizing the color filters CF. Accordingly, the manufacturing efficiency of the display device 10 may be increased. For example, a separate mask process for forming the first light blocking layer BM1 may be omitted, and the manufacturing process of the display device 10 may be simplified or streamlined.

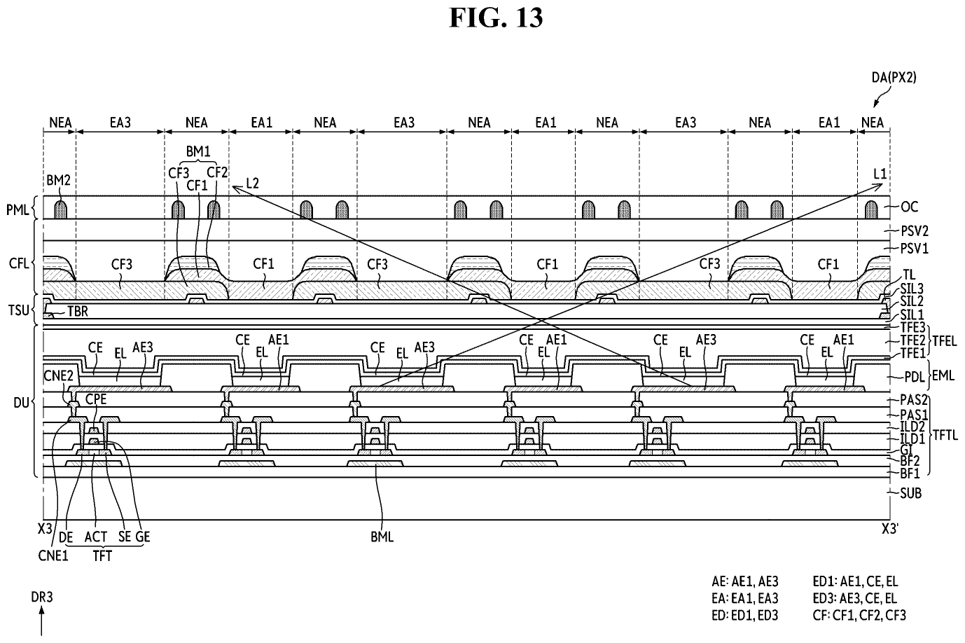

FIG. 13 is a cross-sectional view showing a display device according to one embodiment. For example, FIG. 13 shows a portion of the display device 10 corresponding to the cross section of the second pixels PX2 taken along line X3-X3′ of FIG. 4.

FIG. 13 shows a portion of the display device 10 including the first light blocking layer BM1 formed by stacking color filters CF as in the embodiments of FIGS. 11 and 12. For example, FIG. 13 shows cross sections of the first emission areas EA1 and the third emission areas EA3 of the second pixels PX2 arranged sequentially or alternately along the second direction DR2 in the display device 10 according to the embodiment of FIGS. 11 and 12.

Referring to FIG. 13, the third color filter CF3 may be disposed at the bottom of the color filters CF in the non-emission area NEA. For example, the third color filter CF3 may be disposed at a location where the first light blocking layer BM1 of the display device 10 according to the embodiments of FIGS. 9 and 10 is disposed, and the first color filter CF1 and the second color filter CF2 may be disposed on third color filter CF3.

The first light blocking layer BM1 formed by the color filters CF may transmit light in the front direction and a viewing angle range close thereto, and may appropriately block side light directed to the non-emission area NEA. However, compared to the embodiments of FIGS. 9 and 10, the height at which the first light blocking layer BM1 provides a light blocking function to effectively block or absorb the light of the first color, the light of the second color, and the light of the third color emitted from the light emitting elements ED may increase. For example, the first light blocking layer BM1 may effectively block all of the light of the first color, the light of the second color, and the light of the third color from the portion where at least two color filters CF are stacked. Accordingly, light leakage in which the side light emitted from at least some of the light emitting elements ED leaks out to the periphery thereof may occur.

For example, some of the light of the third color emitted from the third light emitting element ED3 may pass only the third color filter CF3 on the path passing through the non-emission area NEA. For example, among the light of the third color emitted from the third light emitting elements ED3, a first light L1 and a second light L2 that deviate from the front direction at a large angle and proceed at a high angle in the side direction may pass only the third color filter CF3 located in the lower part of the first light blocking layer BM1 in the path passing through the first light blocking layer BM1 and may not pass the first color filter CF1 and the second color filter CF2. Since the first light L1 and the second light L2 are light of the third color, both can pass through the third color filter CF3. Accordingly, the first light L1 and the second light L2 are not appropriately absorbed or blocked by the first light blocking layer BM1 and are emitted to the outside of the display device 10, which may cause light leakage of the side light. For example, in the second light emission mode in which only the second pixels PX2 are driven and the side viewing angle is limited, some of the light emitted from the second pixels PX2 (for example, blue light traveling at a high angle in the side direction) may leak through the non-emission area NEA around the emission area EA. Due to light leakage of the side light, the effect of limiting the side viewing angle in the second light emission mode may be reduced or the image quality of the display device 10 may be deteriorated.

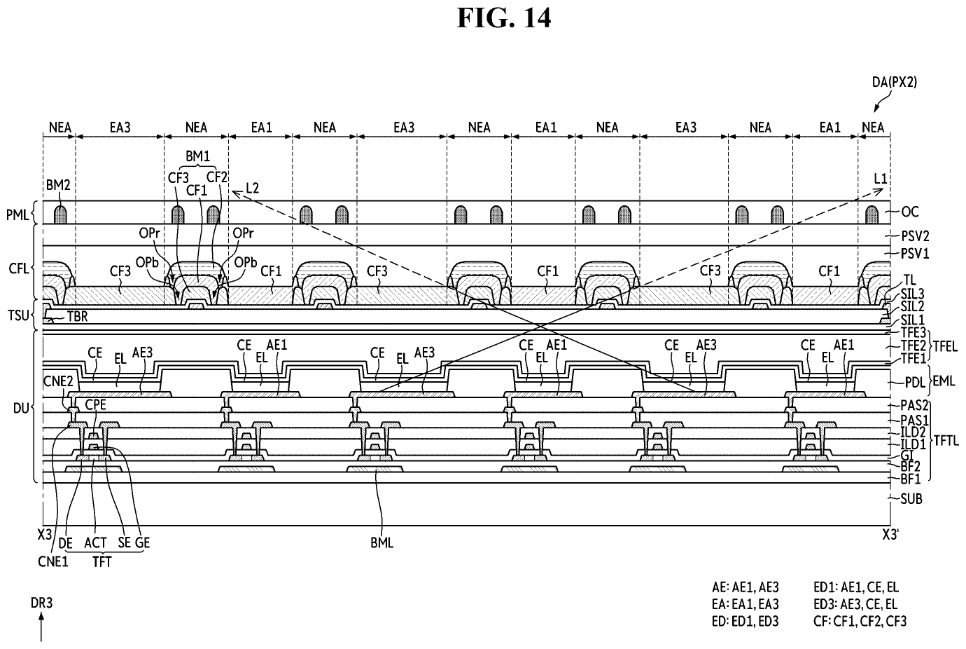

FIG. 14 is a cross-sectional view illustrating a display device according to one embodiment. For example, FIG. 14 shows a portion of the display device 10 corresponding to the cross section of the second pixels PX2 taken along line X3-X3′ of FIG. 4.

FIG. 14 shows a portion of the display device 10 including the first light blocking layer BM1 formed by stacking color filters CF as in the embodiments of FIGS. 11 and 12. FIG. 14 shows a different embodiment from the embodiment of FIG. 13 in relation to the form or structure of the first light blocking layer BM1.

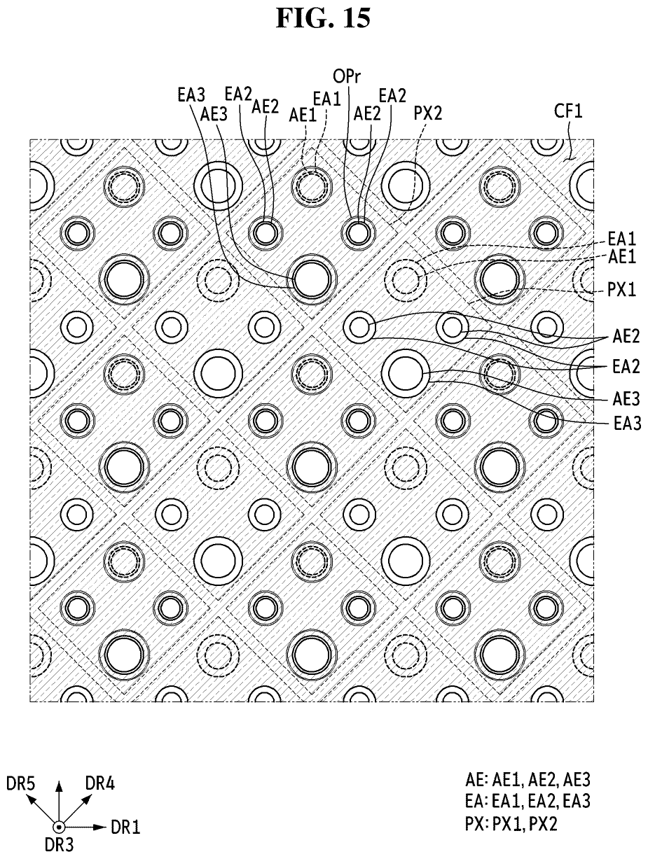

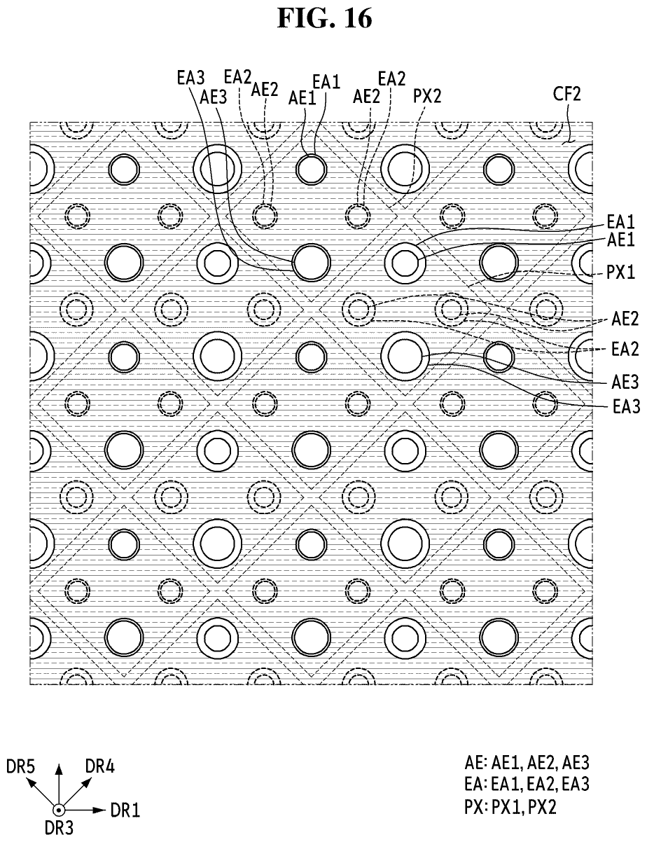

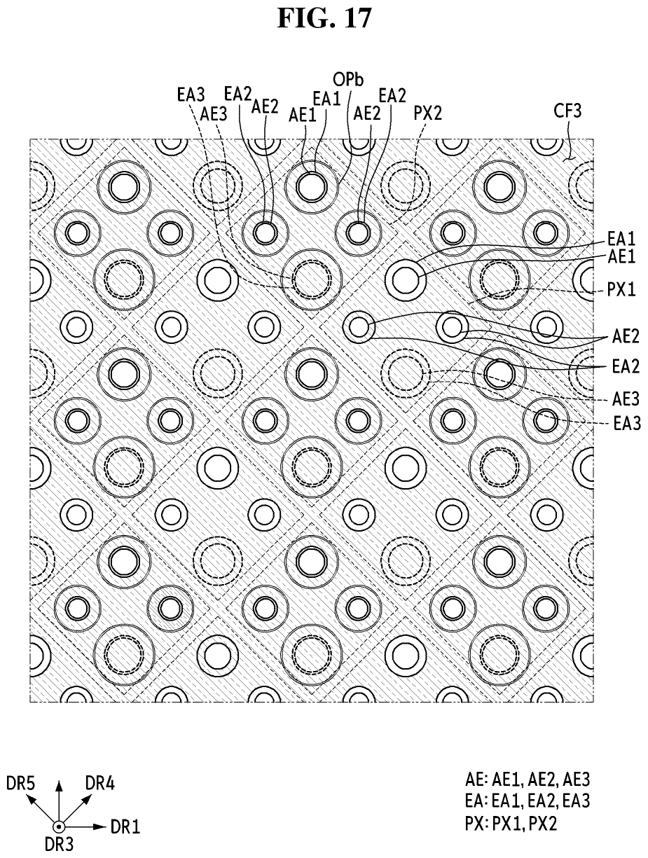

FIG. 15 is a plan view illustrating a first color filter according to one embodiment. FIG. 16 is a plan view illustrating a second color filter according to one embodiment. FIG. 17 is a plan view illustrating a third color filter according to one embodiment. For example, FIGS. 15 to 17 shows the embodiments of the first color filter CF1, the second color filter CF2, and the third color filter CF3, respectively, of the display device 10 in which ring-shaped openings OPr and OPb are formed in at least one color filter CF forming the first light blocking layer BM1 in the non-emission area NEA, as in the embodiment of FIG. 14.

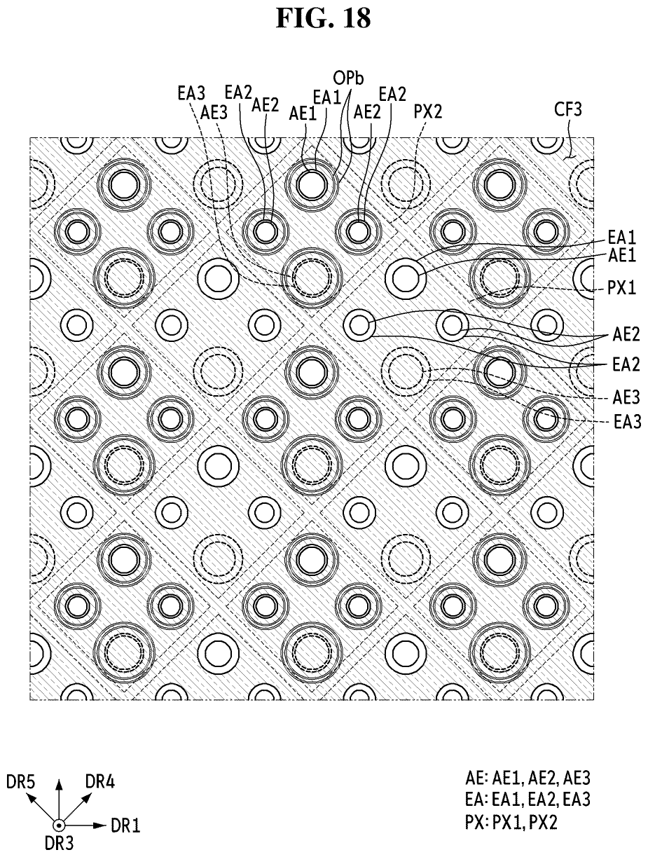

FIGS. 18 to 21 are plan views showing a third color filter according to embodiments. For example, FIGS. 18 to 21 show modified embodiments that are different from each other in respect to the third color filter CF3 according to the embodiment of FIG. 17.

Referring to FIGS. 14 to 21, at least one of the color filters CF forming the first light blocking layer BM1 in the non-emission area NEA may include the ring-shaped openings OPr and OPb surrounding the emission areas EA at the periphery of the emission areas EA of the second pixels PX2 or at the periphery of some emission areas EA among the first emission areas EA1, the second emission areas EA2, and the third emission areas EA3 of the second pixels PX2. For example, the color filter CF disposed at the bottom of the color filters CF forming the first light blocking layer BM1, such as the third color filter CF3 in the embodiment of FIG. 13, may be disposed in the non-emission area NEA of the second pixels PX2 and include the ring-shaped openings OPb surrounding the emission areas EA of the second pixels PX2.

The ring-shaped openings OPb of the third color filter CF3 may be filled with at least one other color filter CF disposed thereon. For example, a portion of the first color filter CF1 may be disposed inside the ring-shaped openings OPb of the third color filter CF3.

By forming ring-shaped openings OPb in the third color filter CF3, side light emitted from the second pixels PX2 may be more effectively blocked. For example, the first light L1 and the second light L2 traveling at a large angle in the side direction (see FIG. 13) among the light of the third color emitted from the third light emitting elements ED3 of the second pixels PX2 may be absorbed by the first color filter CF1 filled in the ring-shaped opening OPb of the third color filter CF3 in the path passing the first light blocking layer BM1 and disappear. Accordingly, light leakage due to side light emitted from the second pixels PX2 may be prevented.

In one embodiment, the ring-shaped openings OPb of the third color filter CF3 may have a ring-shape surrounding the emission areas EA of the second pixels PX2 individually, but the present disclosure is not limited thereto. In addition, the ring-shaped openings OPb of the third color filter CF3 may have a narrow width, but the present disclosure is not limited thereto. For example, the ring-shaped openings OPb of the third color filter CF3 may have any shape and/or size depending on spatial conditions (e.g., the width, area, or shape, etc. of the non-emission area NEA around the emission areas EA of the second pixels PX2) and/or the light blocking effect by the first light blocking layer BM1.

In FIGS. 14 and 17, embodiments in which only one ring-shaped opening OPr or OPb is formed in each of the first color filter CF1 and the third color filter CF3 around each of the emission areas EA of the second pixels PX2 has been disclosed, but the present disclosures are not limited thereto. For example, considering various factors including the width or area of the non-emission area NEA that can be secured at the location where each ring-type opening OPr or OPb is placed, or the light blocking effect by the ring-type opening OPr or OPb, the number or location of the ring-shaped opening OPr or OPb formed in the first color filter CF1 and/or the third color filter CF3 may vary. For one example, as shown in FIG. 18, two or more ring-shaped openings OPb may be disposed in the third color filter CF3 around each of the emission areas EA of the second pixels PX2.

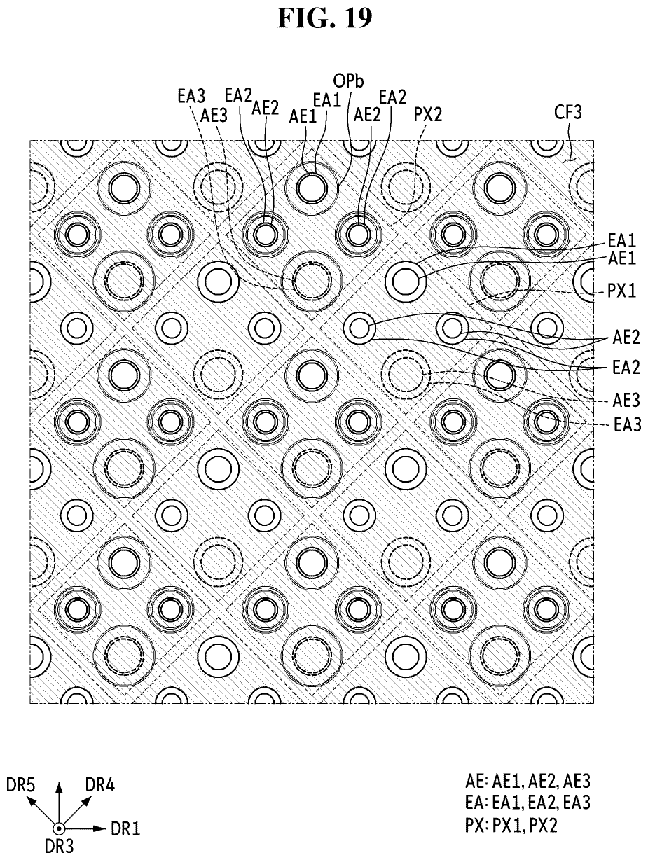

In addition, the number and/or size of the ring-shaped openings OPr and OPb surrounding each of the emission areas EA may be differentiated depending on the width or area of the non-emission area NEA around each of the first emission areas EA1, the second emission areas EA2, and/or the third emission areas EA3. For example, in comparison to the ring-shaped opening OPr or OPb surrounding the first emission area EA1 and/or the ring-shaped opening OPr or OPb surrounding the third emission area EA3, a larger number and/or a wider width of the ring-shaped opening OPr or OPb may be disposed at the periphery of the second emission area EA2 having a smaller size than the first emission area EA1 and the third emission area EA3. For example, as shown in FIG. 19, one ring-shaped opening OPb may be disposed in the third color filter CF3 around the first and third emission areas EA1 and EA3 of each of the second pixels PX2, and two or more ring-shaped openings OPb may be disposed in the third color filter CF3 around each of the second emission areas EA2 of the second pixels PX2. Alternatively, the size of the ring-shaped opening OPb of the third color filter CF3 disposed around the second emission areas EA2 of each of the second pixels PX2 may be larger than the size of ring-shaped opening OPb of the third color filter CF3 disposed at the periphery of each of the first emission area EA1 and the third emission area EA3 of the second pixels PX2. In this way, depending on the embodiments, at least one of the number, size, and shape of the ring-shaped openings OPr and OPb formed around the emission areas EA according to the width or area of the non-emission area NEA located around each of the emission areas EA may be adjusted or differentiated.

In one embodiment, the ring-shaped openings OPr and OPb formed in the at least one color filter CF may not be disposed in the non-emission area NEA of the first pixels PX1, and may be disposed only in the non-emission area NEA of the second pixels PX2. For example, as shown in FIGS. 15 and 17, the ring-shaped openings OPr of the first color filter CF1 and the ring-shaped openings OPb of the third color filter CF3 may be formed in the non-emission area NEA of the second pixels PX2, and the ring-shaped openings OPr and OPb may not be formed in the non-emission area NEA of the first pixels PX1. Accordingly, side light blocking effect (e.g., side light blocking rate) may be more effective in the second pixels PX2 than in the first pixels PX1.

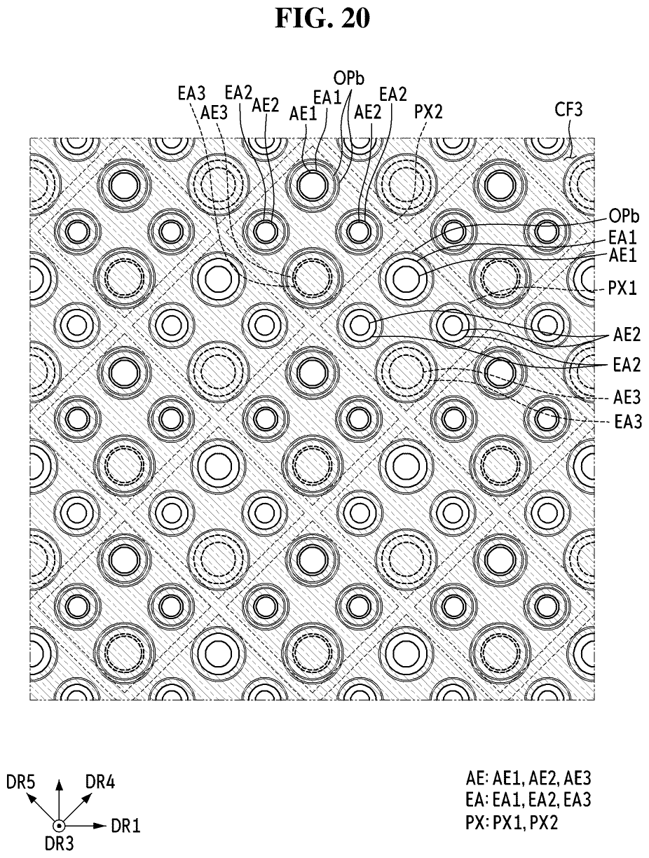

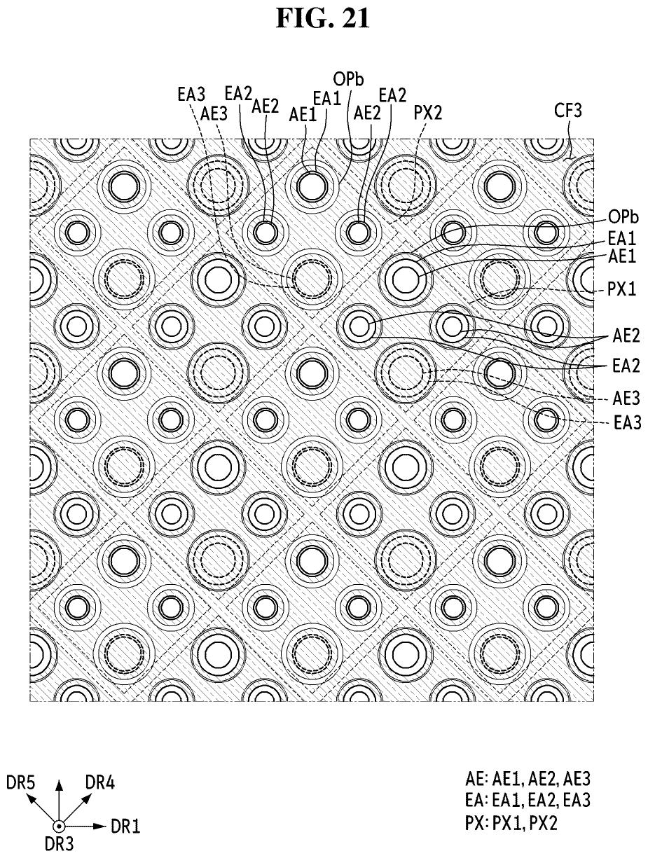

However, the embodiments are not limited to what is explicitly disclosed herein. For example, in another embodiment, the ring-shaped openings OPr and OPb formed in the at least one color filter CF may be formed both in the non-emission area NEA of the first pixels PX1 and the non-emission area NEA of the second pixels PX2. For one example, as shown in FIGS. 20 and 21, the third color filter CF3 may further include the ring-shaped openings OPb surrounding the emission areas EA at the periphery of the emission areas EA of the first pixels PX1, or at the periphery of some emission areas EA among the first emission areas EA1, the second emission areas EA2, and the third emission areas EA3 of the first pixels PX1. The first color filter CF1 may or may not include the ring-shaped openings OPr in the non-emission area NEA of the first pixels PX1 and/or the second pixels PX2.

In one embodiment, the first pixels PX1 may be driven in a first emission mode that provides a wider viewing angle, and the blocking rate of side light in the first emission mode (e.g., the blocking rate of lateral light in the first mode) may be lower than the blocking rate of side light in a second emission mode (e.g., the blocking rate of lateral light in the second mode). In addition, the openings OP of the first light blocking layer BM1 that expose layers in the emission areas EA of the first pixels PX1 may be larger than the openings OP of the first light blocking layer BM1 that expose the layers in the emission areas EA of the second pixels PX2. Accordingly, the non-emission area NEA of the first pixels PX1 may be narrower than the non-emission area NEA of the second pixels PX2.

In one embodiment, ring-shaped openings OPr and OPb of different numbers and/or size may be formed in the first pixels PX1 and the second pixels PX2 considering the area or ratio occupied by the non-emission area NEA in the first pixels PX1 and the second pixels PX2 and/or the blocking rate of side light (e.g., the blocking rate of lateral light) of the first pixels PX1 and the second pixels PX2 respectively, according to the first emission mode and the second emission mode. For example, the number of ring-shaped openings OPr and OPb disposed in the non-emission area NEA of the second pixels PX2 may be greater than the number of ring-shaped openings OPr and OPb disposed in the non-emission area NEA of the first pixels PX1. For example, as shown in FIG. 20, one ring-shaped opening OPb may be formed in the third color filter CF3 around each of the emission areas EA of the first pixels PX1, and two or more ring-shaped openings OPb may be formed in the third color filter CF3 around each of the emission areas EA of the second pixels PX2. Alternatively, the size (e.g., width) of the ring-shaped openings OPr and OPb disposed in the non-emission area NEA of the second pixels PX2 may be larger than the ring-shaped openings OPr and OPb disposed in the non-emission area NEA of the first pixels PX1. For example, as shown in FIG. 21, the same number of ring-shaped openings OPb may be formed in the third color filter CF3 around each of the emission areas EA of the first pixels PX1 and the emission areas EA of the second pixels PX2, but the size of the ring-shaped opening OPb surrounding each of the emission areas EA of the first pixels PX1 and the size of the ring-shaped opening OPb of the third color filter CF3 surrounding each of the emission areas EA of the second pixels PX2 may be different. In one embodiment, ring-shaped openings OPb of larger size may be disposed in the third color filter CF3 around the emission areas EA of the second pixels PX2.

In addition to the above-described embodiments, the shape, number, size, and/or distribution shape of the ring-shaped openings OPb of the third color filter CF3 disposed at the bottom of the first light blocking layer BM1 may be modified in various ways.

The color filters CF disposed on the third color filter CF3 in the non-emission area NEA may or may not include ring-shaped openings surrounding the emission areas EA of at least some of the pixels PX including the second pixels PX2. For example, the first color filter CF1 disposed at the middle layer of the first light blocking layer BM1 may selectively include ring-shaped openings OPr surrounding the emission areas EA at the periphery of the emission areas EA of the second pixels PX2 or some emission areas EA among the first emission areas EA1, the second emission areas EA2, and the third emission areas EA3 of the second pixels PX2.

For one example, as shown in FIGS. 14 and 15, the first color filter CF1 may include ring-shaped openings OPr disposed in the non-emission area NEA. In plan view (or when viewed in the third direction), the ring-shaped openings OPr of the first color filter CF1 may not overlap the ring-shaped openings OPb of the third color filter CF3. The ring-shaped openings OPr of the first color filter CF1 may be filled with the second color filter CF2. For example, one portion of the second color filter CF2 may be disposed inside of the ring-shaped openings OPr of the first color filter CF1. Accordingly, side light emitted from the second pixels PX2 may be more effectively blocked.

In an embodiment in which the first color filter CF1 includes the ring-shaped openings OPr, the shape, size, number, and/or distribution shape of the ring-shaped openings OPr formed in the first color filter CF1 may vary depending on the embodiments. For example, similarly to various embodiments described above in relation to the ring-shaped openings OPb of the third color filter CF3, the ring-shaped openings OPr of various shape, size, and/or the numbers of the first color filter CF1 may be formed depending on the spatial conditions (e.g., width, area, or shape of the non-emission area NEA) corresponding to the location of the ring-shaped openings OPr of the first color filter CF1 and/or the light blocking effect by the first light blocking layer BM1.

In one embodiment, as shown in FIGS. 14 and 16, the second color filter CF2 disposed at the uppermost portion of the color filters CF forming the first light blocking layer BM1 may not be opened in the non-emission area NEA. For example, the second color filter CF2 may not include ring-shaped openings in the non-emission area NEA. Accordingly, light blocking effect may be provided in the non-emission area NEA by the first light blocking layer BM1.

In the display device 10 according to the above-described embodiments, the light exit angle or side viewing angle of some pixels PX (e.g., second pixels PX2) among the pixels PX of the display area DA may be limited to be narrower than the light exit angle or side viewing angle of the other pixels PX (e.g., first pixels PX1) by the first light blocking layer BM1 and the second light blocking layer BM2. In the display device 10 according to embodiments, the side viewing angle of the image displayed in the display area DA may be modified (for example, controlled or changed) by selectively driving the pixels PX according to the user's selection. For example, when the display device 10 is driven in the first emission mode according to the user's selection, the image may be viewed not only from the front direction but the side direction since both the first pixels PX1 and the second pixels PX2 are activated to display an image. On the other hand, when the display device 10 is driven in the second emission mode according to the user's selection, the side viewing angle may be limited to be narrow since the first pixels PX1 are not activated and only the second pixels PX2 are activated to display an image. Accordingly, only the users located in the front direction of the display device 10 may view the image substantially. The display device 10 according to the embodiments may modify viewing angle of the display device 10 depending on application, to account for factors such as privacy protection, thereby increasing convenience of use.

In addition, in the display device 10 according to some embodiments (e.g., the embodiments of FIGS. 11 to 21), the first light blocking layer BM1 may be formed by overlapping the color filters CF in the non-emission area NEA. Accordingly, the manufacturing efficiency of the display device 10 may be increased.

Moreover, in the display device 10 according to some embodiments (e.g., the embodiments of FIGS. 14 to 21), in the non-emission area NEA of at least some pixels PX among the pixels PX disposed in the display area DA, the ring-shaped openings OPr and OPb may be formed in at least one color filter CF including the third color filter CF3 disposed at the lowermost portion of the first light blocking layer BM1. The ring-shaped openings OPr and OPb may be filled with at least one color filter (e.g., first color filter CF1 or second color filter CF2) disposed thereon. Accordingly, light leakage of side light emitted from the pixels PX in which the ring-shaped openings OPr and OPb is formed in the first light blocking layer BM1 may be effectively prevented.

In some embodiments, the ring-shaped openings OPr and OPb formed in the first light blocking layer BM1 may be disposed in some pixels PX2 with more limited light exit angle or side viewing angle. For example, the ring-shaped openings OPr and OPb may be formed in the first light blocking layer BM1 in the second pixels PX2 having a relatively small size of the emission areas EA with layers exposed by the first light blocking layer BM1 in comparison to the first pixels PX1 and having a more limited side viewing angle by the second light blocking layer BM2. Light leakage of side light emitted from the second pixels PX2 may be effectively blocked by the ring-shaped openings OPr and OPb formed in the first light blocking layer BM1. Accordingly, in the second emission mode in which only the second pixels PX2 are selectively driven, it is possible to effectively prevent the image from being viewed from the side or the image quality from being degraded.

In conclusion, those skilled in the art will appreciate that many variations and modifications can be made to the embodiments without substantially departing from the principles of the present disclosure. Therefore, the disclosed embodiments are used in a generic and descriptive sense only and not for purposes of limitation.

What is claimed is:

1. A display device comprising:
pixels, each pixel of the pixels comprising emission areas including a first emission area, a second emission area, and a third emission area, and light emitting elements disposed in the emission areas;
a first color filter disposed on the light emitting elements and disposed in the first emission areas of the pixels and a non-emission area at the periphery of the emission areas;
a second color filter disposed on the light emitting elements and disposed in the second emission areas of the pixels and the non-emission area;
a third color filter disposed on the light emitting elements and disposed in the third emission areas of the pixels and the non-emission area;
a first light blocking layer formed by overlapping at least two of the first color filter, the second color filter, and the third color filter in the non-emission area; and
a second light blocking layer disposed on the first light blocking layer and surrounding the emission areas of a subgroup of the pixels,
wherein the color filter disposed at the lowermost portion of the first light blocking layer among the first color filter, the second color filter, and the third color filter includes ring-shaped openings surrounding the emission areas of the subgroup of pixels.

2. The display device of claim 1,
wherein the ring-shaped openings are filled with other color filter disposed on the color filter that is at the bottom of the first light blocking layer.

3. The display device of claim 1,
wherein the pixels comprise first pixels and second pixels, and wherein the second light blocking layer is disposed in the second pixels and absent from the first pixels, and
the second light blocking layer is disposed in the non-emission area of the second pixels and surrounds the emission areas of the second pixels.

4. The display device of claim 3,
wherein the ring-shaped openings are absent from the non-emission area of the first pixels and disposed in the non-emission area of the second pixels.

5. The display device of claim 3,
wherein the ring-shaped openings are disposed in the non-emission area of the first pixels and in the non-emission area of the second pixels.

6. The display device of claim 5,
wherein the number of the ring-shaped openings disposed in the non-emission area of the first pixels and the number of the ring-shaped openings disposed in the non-emission area of the second pixels are different.

7. The display device of claim 5,
wherein the size of the ring-shaped openings disposed in the non-emission area of the first pixels and the size of the ring-shaped openings disposed in non-emission area of the second pixels are different.

8. The display device of claim 7,
wherein the size of the ring-shaped openings disposed in the non-emission area of the second pixels is larger than the size of the ring-shaped openings disposed in the non-emission area of the first pixels.

9. The display device of claim 3,
wherein the first light blocking layer comprises openings in the emission areas of the first pixels and openings in the emission areas of the second pixels, and
the size of the openings of the first light blocking layer in the emission areas of the first pixels and the size of the openings of the first light blocking layer in the emission areas of the second pixels are different.

10. The display device of claim 9,
wherein the light emitting elements comprise respective pixel electrodes disposed in the emission areas of the first pixels and the second pixels, respective light emitting layers disposed on the pixel electrodes, and a common electrode disposed on the light emitting layers.

11. The display device of claim 10,
wherein a separation distance between the openings of the first light blocking layer in the emission areas of the first pixels and the pixel electrodes disposed in the first pixels is greater than a separation distance between the openings of the first light blocking layer in the emission areas of the second pixels and the pixel electrodes disposed in the second pixels.

12. The display device of claim 1,
wherein the sizes of the first emission area, the second emission area, and the third emission area of each pixel are different.

13. The display device of claim 12,
wherein, in the subgroup of pixels, at least one of the size and the number of two or more ring-shaped openings among the ring-shaped opening of the first light blocking layer surrounding the first emission area, the ring-shaped opening of the first light blocking layer surrounding the second emission area, and the ring-shaped opening of the first light blocking layer surrounding the third emission area is different.

14. The display device of claim 1,
wherein the color filter disposed on the middle layer of the first light blocking layer among the first color filter, the second color filter, and the third color filter comprises ring-shaped openings surrounding the emission areas of the subgroup of pixels.

15. The display device of claim 14,
wherein the ring-shaped openings of the color filter disposed at the middle layer of the first light blocking layer do not overlap the ring-shaped openings of the color filter disposed at the lowermost portion of the first light blocking layer.

16. The display device of claim 1,
wherein the color filter disposed at the uppermost portion of the first blocking layer among the first color filter, the second color filter, and the third color filter does not comprise ring-shaped openings in the non-emission area.

17. The display device of claim 1,
wherein each of the pixels comprises a first light emitting element disposed in the first emission area and emitting red light, a second light emitting element disposed in the second emission area and emitting green light, and a third light emitting element disposed in the third emission area and emitting blue light,
wherein the first color filter, the second color filter, and the third color filter selectively transmit the red light, the green light, and the blue light, respectively.

18. The display device of claim 17,
wherein the first or third color filter is disposed on the lowermost portion of the first light blocking layer in the non-emission area, and
the second color filter is disposed on the uppermost portion of the first light blocking layer in the non-emission area.

19. An electronic device comprising:
a display device comprising first pixels, second pixels, and a display driver transmitting data to the first pixels and second pixels to display images;
wherein each of the second pixels comprises:
a first emission area, a second emission area, and a third emission area separated by a non-emission area,
a first light blocking layer comprising a lower color filter and an upper color filter that overlap in the non-emission area; and
a second light blocking layer disposed on the first light blocking layer and surrounding the first emission area, the second emission area, and the third emission area,
wherein the lower color filter of the first light blocking layer includes ring-shaped openings surrounding the first emission area, the second emission area, and the third emission area.

20. The electronic device of claim 19, wherein the second light blocking layer is absent in the first pixels.
